(19) United States
(12) Patent Application Publication
(10) Pub. No.: US 2019/0131348 A1
(43) Pub. Date: May 2, 2019

(54) SEMICONDUCTOR MEMORY DEVICE INCLUDING A LINE-TYPE SELECTION INTERCONNECTION, AND AN ELECTRONIC SYSTEM INCLUDING SEMICONDUCTOR MEMORY DEVICE

(71) Applicant: SK hynix Inc., Icheon (KR)

(72) Inventor: Young-Seok KO, Suwon (KR)

(21) Appl. No.: 16/020,856

(22) Filed: Jun. 27, 2018

(30) Foreign Application Priority Data
Oct. 30, 2017 (KR) 10-2017-0142534

(51) Int. Cl. H01L 27/24; H01L 45/00; G11C 13/00; H01L 23/528; H01L 27/22; H01L 43/02; H01L 43/08; G11C 11/16

(52) U.S. Cl. CPC H01L 27/2481; H01L 45/1233; H01L 45/1253; H01L 45/144; G11C 11/1653; H01L 23/528; H01L 27/222; H01L 43/02; H01L 43/08; G11C 13/0023

(57) ABSTRACT

Semiconductor memory devices and electronic systems having the semiconductor memory devices are provided. One of the semiconductor memory device may include a plurality of first conductive interconnections extending in parallel in a first horizontal direction, a plurality of selection interconnections disposed on the first conductive interconnections, the selection interconnections extending in parallel in the first horizontal direction, a plurality of second conductive interconnections extending in parallel in a second horizontal direction that is perpendicular to the first horizontal direction, and a plurality of memory cell stacks respectively disposed in interconnection regions between the first conductive interconnections and the second conductive interconnections. Each of the memory cell stacks may include a variable resistive element.

### CROSS-REFERENCE TO RELATED APPLICATION

The present application claims priority to Korean Patent Application No. 10-2017-0142534, filed on Oct. 30, 2017, which is incorporated herein by reference in its entirety.

### BACKGROUND

### 1. Field

Embodiments of the present disclosure relate to semiconductor memory devices including line-type selection interconnections, to methods of manufacturing the semiconductor memory devices that include the line-type selection interconnections, and to electronic systems including the semiconductor memory devices that include the line-type selection interconnections.

### 2. Description of the Related Art

Variable resistive memory devices, as well as other types of semiconductor memory devices, each switch between a low resistance state and a high resistance state. For example, a variable resistive memory device may include one of a Resistive Random Access Memory (ReRAM), a Phase Changeable Random Access Memory (PCRAM), a Spin Transfer Torque Magneto-resistive Random Access Memory (STT-MRAM), and another type of memory device.

A variable resistive semiconductor memory device may have a cross-point arrangement structure. That is, the memory device may include an array of memory cells that are vertically arranged in intersection regions between sets of horizontal lines. Since memory devices with cross-point arrangement structures are relatively simple, and have nonvolatile characteristics compared to a DRAM (Dynamic Random Access Memory), they are attracting attention as next generation semiconductor memory devices.

### SUMMARY

Embodiments of the present disclosure provide semiconductor memory devices including line-type selection interconnections.

Embodiments of the present disclosure provide methods of fabricating semiconductor memory devices that include line-shaped selection interconnections.

Embodiments of the present disclosure provide electronic systems, which include a semiconductor memory device including a line-shaped selection interconnection.

In accordance with an embodiment of the present disclosure, an electronic system may include a semiconductor memory device. The semiconductor memory device may include a plurality of first conductive interconnections extending in parallel in a first horizontal direction, a plurality of selection interconnections disposed on the first conductive interconnections, the selection interconnections extending in parallel in the first horizontal direction, a plurality of second conductive interconnections extending in parallel in a second horizontal direction that is perpendicular to the first horizontal direction, and a plurality of memory cell stacks respectively disposed in interconnection regions between the first conductive interconnections and the second conductive interconnections. Each of the memory cell stacks may include a variable resistive element.

In accordance with an embodiment of the present disclosure, an electronic system may include a semiconductor memory device. The semiconductor memory device may include first conductive interconnections extending in parallel in a first horizontal direction, selection interconnections extending in parallel in a second horizontal direction that is perpendicular to the first horizontal direction, second conductive interconnections disposed on the selection interconnections, the second conductive interconnections extending in parallel in the second horizontal direction, and memory cell stacks respectively disposed in intersection regions between the first conductive interconnections and the selection interconnections. Each of the memory cell stacks may include a variable resistive element.

In accordance with an embodiment of the present disclosure, a semiconductor memory device may include first conductive interconnections extending in parallel in a first horizontal direction, second conductive interconnections extending in parallel in a second horizontal direction that is perpendicular to the first horizontal direction, memory cell stacks respectively disposed in intersection regions between the first conductive interconnection and the second conductive interconnections, and selection interconnections disposed between the first conductive interconnections and the memory cell stacks. The selection interconnections are in contact with the first conductive interconnections and extend in parallel in the first horizontal direction.

### BRIEF DESCRIPTION OF THE DRAWINGS

FIG. 1 is a circuit diagram schematically illustrating a semiconductor memory device in accordance with an embodiment of the present disclosure.

FIGS. 2A to 2D are three-dimensional perspective views schematically illustrating semiconductor memory devices in accordance with embodiments of the present disclosure.

FIGS. 3A and 3B are cross-sectional views of a semiconductor memory device shown in FIG. 2A in accordance with an embodiment of the present disclosure.

FIGS. 4A and 4B are cross-sectional views of a semiconductor memory device shown in FIG. 2B in accordance with an embodiment of the present disclosure.

FIGS. 5A and 5B are cross-sectional views of a semiconductor memory device shown in FIG. 2C in accordance with an embodiment of the present disclosure.

FIGS. 6A and 6B are cross-sectional views of a semiconductor memory device shown in FIG. 2D in accordance with an embodiment of the present disclosure.

FIGS. 7A and 7B to FIGS. 10A and 10B are cross-sectional views illustrating a method of forming the semiconductor memory device shown in FIG. 2A in accordance with an embodiment of the present disclosure.

FIGS. 11A and 11B to FIGS. 14A and 14B are cross-sectional views illustrating a method of forming the semiconductor memory device shown in FIG. 2B in accordance with an embodiment of the present disclosure.

FIGS. 15A and 15B to FIGS. 20A and 20B are cross-sectional views illustrating a method of forming the semiconductor memory device shown in FIG. 2C in accordance with an embodiment of the present disclosure.

FIGS. 21A and 21B to FIGS. 26A and 26B are cross-sectional views illustrating a method of forming the semiconductor memory device shown in FIG. 2D in accordance with an embodiment of the present disclosure.

FIGS. 27 to 31 are electronic systems that each include one or more semiconductor memory devices in accordance with embodiments of the present disclosure.

### DETAILED DESCRIPTION

Various embodiments will be described below in more detail with reference to the accompanying drawings. Embodiments of the present disclosure may, however, be in different forms and should not be construed as being limited to the embodiments set forth herein. Rather, these embodiments are provided so that this disclosure will be thorough and complete, and will fully convey the scope of the present disclosure to those skilled in the art.

The terms used in this specification are only used for describing exemplary embodiments, and do not limit embodiments of the present disclosure. The terms of a singular form may include plural forms unless referred to the contrary. The meaning of ‘comprise’ and ‘comprising’ used in this specification specifies a component, step, operation, and/or element, but does not exclude other components, steps, operations, and/or elements.

Throughout the specification, like reference numerals refer to the same elements. Therefore, although the same or similar reference numerals are not mentioned or described in the corresponding drawing, the reference numerals may be described with reference to other drawings. Furthermore, although elements are not represented by reference numerals, the elements may be described with reference to other drawings.

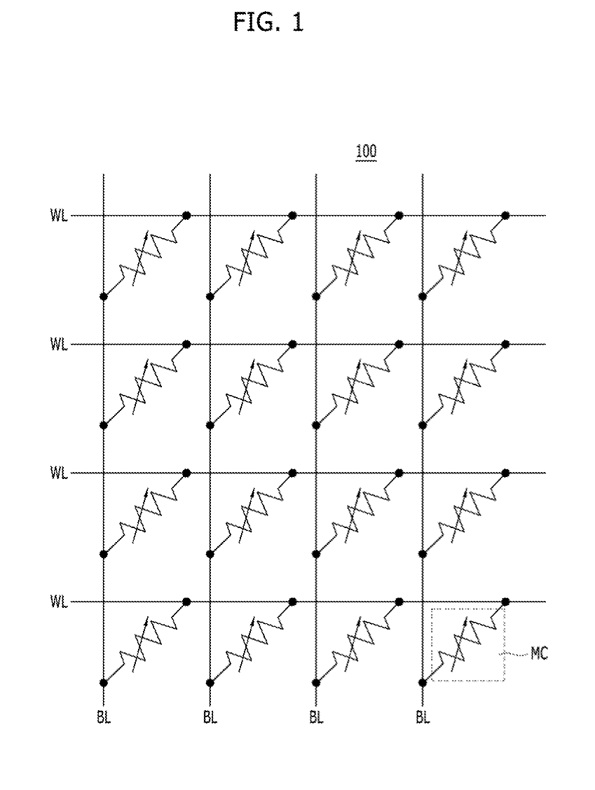

FIG. 1 is a circuit diagram schematically illustrating a semiconductor memory device 100 in accordance with an embodiment of the present disclosure. The semiconductor memory device 100 may have a cross-point array structure. The cross-point array structure may also be referred to as a cross-point arrangement structure.

Referring to FIG. 1, the semiconductor memory device 100 in accordance with an embodiment of the present disclosure may include a plurality of word lines WL, a plurality of bit lines BL, and a plurality of memory cells MC. The word lines WL may extend in a first direction (i.e., a row direction), and may be in parallel with each other. The bit lines BL may extend in a second direction (i.e., a column direction) that is perpendicular to the first direction, and may be in parallel with each other. The memory cells MC may be disposed between the word lines WL and the bit lines BL. For example, the memory cells MC may be disposed in regions where the word lines WL and the bit lines BL intersect in a direction that is perpendicular to the first and second directions. The memory cells MC may be electrically connected between the word lines WL and the bit lines BL. The memory cells MC may each include a variable resistive element. In another embodiment, the word lines WL may extend in the second direction (i.e., the column direction), and the bit lines BL may extend in the first direction (i.e., the row direction).

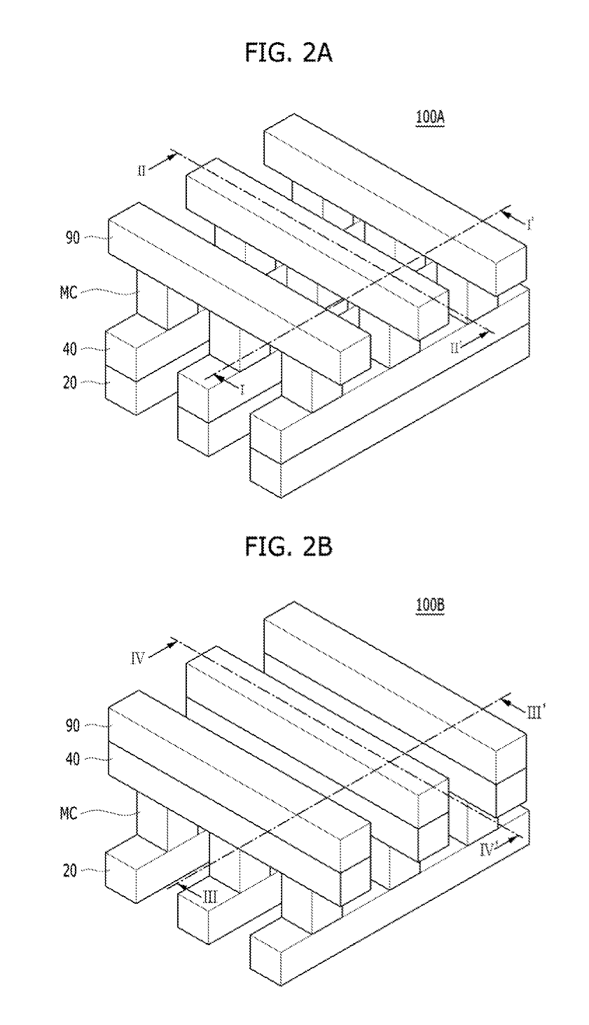

FIGS. 2A to 2D are three-dimensional perspective views schematically illustrating semiconductor memory devices 100A to 100D in accordance with embodiments of the present disclosure.

Referring to FIG. 2A, a semiconductor memory device 100A in accordance with an embodiment of the present disclosure may include a plurality of lower conductive interconnections 20, a plurality of selection interconnections 40 disposed on the lower conductive interconnections 20, a plurality of upper conductive interconnections 90, and a plurality of memory cell stacks MC. The lower conductive interconnections 20 and the selection interconnections 40 may each extend in a first horizontal direction. The upper conductive interconnections 90 may each extend in a second horizontal direction that is perpendicular to the first horizontal direction. The plurality of memory cell stacks MC may be disposed in intersection regions between the lower conductive interconnections 20 and the upper conductive interconnections 90. As illustrated in FIG. 2A, the plurality of memory cell stacks MC may be disposed between the selection interconnections 40 and the upper conductive interconnections 90.

With further reference to FIG. 1, the lower conductive interconnections 20 may be the word lines WL of FIG. 1, and the upper conductive interconnections 90 may be the bit lines BL of FIG. 1. Alternatively, in another embodiment of the present disclosure, the lower conductive interconnections 20 may be the bit lines BL, and the upper conductive interconnections 90 may be the word lines WL. The lower conductive interconnections 20 and the upper conductive interconnections 90 may include one or more conductive materials, such as metals, metal nitrides, metal alloys, metal compounds, or combinations thereof.

The selection interconnections 40 may be directly stacked on the lower conductive interconnections 20. Like the lower conductive interconnections 20, the selection interconnections 40 may have line-shapes extending in the first horizontal direction. The lower conductive interconnections 20 and the selection interconnections 40 may vertically overlap, such that sidewalls of the selection interconnections 40 and sidewalls of the lower conductive interconnections 20 are vertically aligned with each other. The selection interconnections 40 may include an Ovonic Threshold Switch (OTS) material layer; a Metal-Insulator Transition (MIT) material layer including an MIT material, such as any of vanadium di-oxide (VO₂) and niobium oxide (NbO₂); a Mixed Ionic Electronic Conduction (MIEC) material layer; a Metal-Insulator-Metal (MIM) stack layer; a metal oxide layer including a metal oxide material, such as hafnium oxide (HfOₓ); a metal-doped silicon oxide layer; a chalcogenide material layer; a phase changeable material layer including a phase changeable material, such as GST (GeSbTe); a switching material layer including a switching structure, such as a diode; or a combination thereof.

The plurality of memory cell stacks MC may have pillar shapes or via plug shapes. The plurality of memory cell stacks MC may have any of circular pillar shapes, square pillar shapes, and various other geometric shapes depending on manufacturing methods used to produce the memory cell stacks MC. The memory cell stacks MC may include variable resistive elements.

Referring to FIG. 2B, a semiconductor memory device 100B in accordance with an embodiment of the present disclosure includes a plurality of lower conductive interconnections 20, a plurality of selection interconnections 40, a plurality of upper conductive interconnections 90 disposed on the plurality of selection interconnections 40, and a plurality of memory cell stacks MC. The plurality of lower conductive interconnections 20 may each extend in a first horizontal direction. The plurality of selection interconnections 40 and the upper conductive interconnections 90 may each extend in a second horizontal direction that is perpendicular to the first horizontal direction. The plurality of memory cell stacks MC may be disposed in interconnection regions between the lower conductive interconnections 20 and the selection interconnections 40. As illustrated in FIG. 2B, the plurality of memory cell stacks MC may be disposed between the lower conductive interconnections 20 and the upper interconnections 40.

With further reference to FIG. 1, the lower conductive interconnections 20 may be the word lines WL of FIG. 1, and the upper conductive interconnections 90 may be the bit lines BL of FIG. 1. Alternatively, in another embodiment of the present disclosure, the lower conductive interconnections 20 may be the bit lines BL of FIG. 1, and the upper conductive interconnections 90 may be the word lines WL of FIG. 1.

The selection interconnections 40 may be disposed between the memory cell stacks MC and the upper conductive interconnections 90. Like the upper conductive interconnections 90, the selection interconnections 40 may have line shapes extending in the second horizontal direction. Specifically, the selection interconnections 40 and the upper conductive interconnections 90 may vertically overlap, such that sidewalls of the selection interconnections 40 and the upper conductive interconnections 90 may be vertically aligned with each other. For example, the upper conductive interconnections 90 may be directly stacked on the selection interconnections 40 and may co-extend in the same direction as the selection interconnections 40.

Referring to FIG. 2C, a semiconductor memory device 100C in accordance with an embodiment of the present disclosure may be similar to the semiconductor memory device 100A shown in FIG. 2A, and further include a plurality of lower barrier interconnections 30 between the lower conductive interconnections 20 and the selection interconnections 40, respectively. Like the lower conductive interconnections 20 and/or the selection interconnections 40, the lower barrier interconnections 30 may have line shapes extending in the first horizontal direction. In addition, sidewalls of the lower conductive interconnections 20, sidewalls of the lower barrier interconnections 30, and sidewalls of the selection interconnections 40 may be vertically aligned with each other. The lower barrier interconnections 30 may include a metal, such as any of tungsten (W), titanium (Ti), tantalum (Ta), aluminum (Al), and copper (Cu); a metal compound, such as any of tungsten nitride (WN), titanium nitride (TiN), and tantalum nitride (TaN); a carbon(C)-containing conductor; another type of conductive material, or a combination thereof.

Referring to FIG. 2D, a semiconductor memory device 100D in accordance with an embodiment of the present disclosure may have a similar structure to the semiconductor memory device 100B shown in FIG. 2B, and further include a plurality of upper barrier interconnections 80 between the selection interconnections 40 and the upper conductive interconnections 90. Like the upper conductive interconnections 90 and/or the selection interconnections 40, the upper barrier interconnections 80 may have line shapes extending in the second horizontal direction. In addition, sidewalls of the upper conductive interconnections 90, sidewalls of the upper barrier interconnections 80, and sidewalls of the selection interconnections 40 may be vertically aligned with each other. The upper barrier interconnections 80 may include a metal, such as any of tungsten (W), titanium (Ti), tantalum (Ta), aluminum (Al), and copper (Cu); a metal compound, such as any of tungsten nitride (WN), titanium nitride (TiN), and tantalum nitride (TaN); a conductor containing carbon (C); another type of conductive material; or a combination thereof.

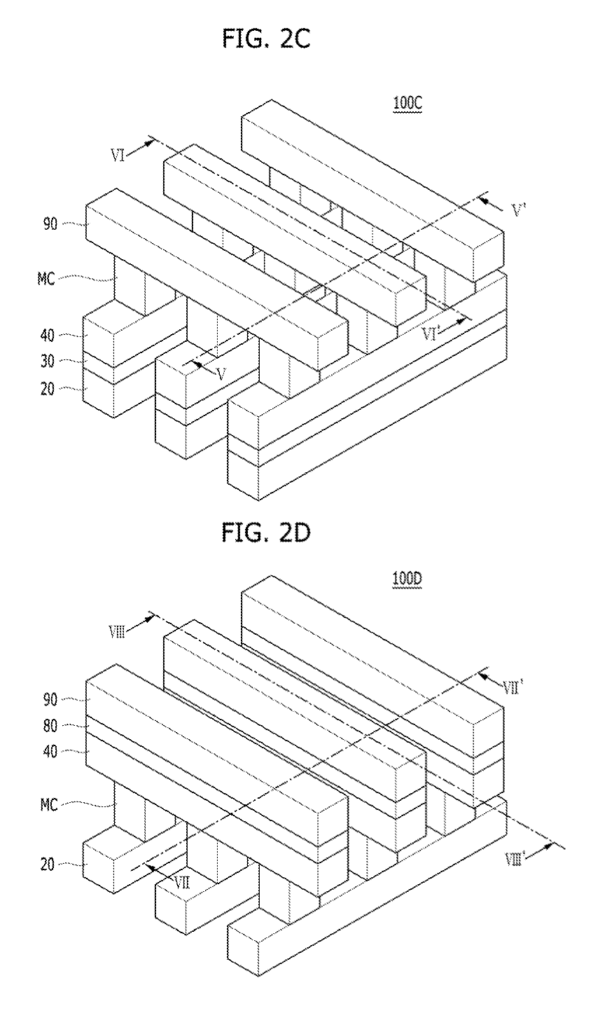

FIGS. 3A and 3B are cross-sectional views of the semiconductor memory device 100A shown in FIG. 2A in accordance with an embodiment of the present disclosure. The cross-sectional views of the semiconductor memory device 100A are taken along lines I-I′ and II-II′ of FIG. 2A.

Referring to FIGS. 3A and 3B, the semiconductor memory device 100A in accordance with an embodiment of the present disclosure may include lower conductive interconnections 20 stacked on a lower layer 10, selection interconnections 40 disposed on the lower conductive interconnections 20, memory cell stacks MC disposed on the selection interconnections 40, and upper conductive interconnections 90 disposed on the memory cell stacks MC.

The lower layer 10 may include a semiconductor substrate, such as a silicon wafer. The lower layer 10 may include an insulating layer including an insulating material, such as silicon oxide, silicon nitride, or a combination thereof.

The lower conductive interconnections 20 may have line shapes extending in a first horizontal direction. With further reference to FIG. 1, the lower conductive interconnections 20 may be the word lines WL of FIG. 1. In another embodiment of the present disclosure, the lower conductive interconnections 20 may be the bit lines BL of FIG. 1. The lower conductive interconnection 20 may include a conductive material, such as a metal, a metal alloy, a metal compound, or a combination thereof.

The selection interconnections 40 may be disposed on the lower conductive interconnections 20, such that the selection interconnections 40 and the lower conductive interconnections 20 are vertically overlapped and aligned with each other. Like the lower conductive interconnection 20, the selection interconnections 40 may have line shapes extending in the first horizontal direction. For example, sidewalls of the selection interconnections 40 and sidewalls of the lower conductive interconnections 20 may be vertically aligned with each other. The selection interconnections 40 may each include an Ovonic Threshold Switch (OTS) material layer; a Metal-Insulator Transition (MIT) material layer including an MIT material, such as vanadium di-oxide (VO₂) or niobium oxide (NbO₂); a Mixed Ionic Electronic Conduction (MIEC) material layer; a Metal-Insulator-Metal (MIM) stack layer; a metal oxide layer including a metal oxide material, such as hafnium oxide (HfOₓ); a metal-doped silicon oxide layer; a chalcogenide material layer; a phase changeable material layer including a phase changeable material, such as GST (GeSbTe); a switching material layer including a switching structure, such as a diode; or a combination thereof.

The memory cell stacks MC may be disposed in intersection regions between the selection interconnections 40 and the upper conductive interconnections 90. The memory cell stacks MC may have square pillar shapes, circular pillar shapes, or any of various other geometric shapes. The memory cell stacks MC may respectively include intermediate electrodes 50, variable resistive elements 60, and upper electrodes 70.

The intermediate electrodes 50 may be respectively disposed between the selection interconnections 40 and the variable resistive elements 60. The intermediate electrodes 50 may respectively include diffusion barrier layers for blocking the diffusion of atoms between the selection interconnections 40 and the variable resistive elements 60. For example, each of the intermediate electrodes 50 may include a metal, such as any of tungsten (W), titanium (Ti), tantalum (Ta), aluminum (Al), and copper (Cu); a metal compound, such as any of tungsten nitride (WN), titanium nitride (TiN), and tantalum nitride (TaN); a conductor containing carbon (C); another type of conductive material; or a combination thereof.

The variable resistive elements 60 may include one or more materials including transition metal oxides; phase changeable materials, such as GST (GeSbTe); magneto-resistive materials, such as any of Co, Fe, and Ni; another type of variable resistive material; or a combination thereof. Accordingly, the semiconductor memory device 100A may be a resistive RAM (ReRAM), a phase changeable RAM (PcRAM), a magneto-resistive RAM (MRAM), or another type of variable resistive memory device.

The upper electrodes 70 may be disposed between the variable resistive elements 60 and the upper conductive interconnections 90. The upper electrodes 70 may include diffusion barrier layers for blocking the diffusion of atoms between the variable resistive elements 60 and the upper conductive interconnections 90. For example, the upper electrodes 70 may include a metal, such as any of tungsten (W), titanium (Ti), tantalum (Ta), aluminum (Al), and copper (Cu); a metal compound, such as any of tungsten nitride (WN), titanium nitride (TiN), and tantalum nitride (TaN); a conductor containing carbon (C); another type of conductive material; or a combination thereof.

An interlayer insulating layer ILD may fill spaces between the lower conductive interconnections 20, spaces between the selection interconnections 40, spaces between the memory cell stacks MC, and spaces between the upper conductive interconnections 90. The interlayer insulating layer ILD may include silicon oxide, silicon nitride, silicon, carbon (C), hydrogen (H), or a combination thereof. In another embodiment of the present disclosure, air gaps may present between the memory cell stacks MC instead of the interlayer insulating layer ILD.

The upper conductive interconnections 90 may extend in a second horizontal direction that is perpendicular to the first horizontal direction. With further reference to FIG. 1, the upper conductive interconnections 90 may be the bit lines BL of FIG. 1. In another embodiment, the upper conductive interconnections 90 may be the word lines WL of FIG. 1. The upper conductive interconnections 90 may include a conductor, such as a metal, a metal alloy, a metal compound, or a combination thereof.

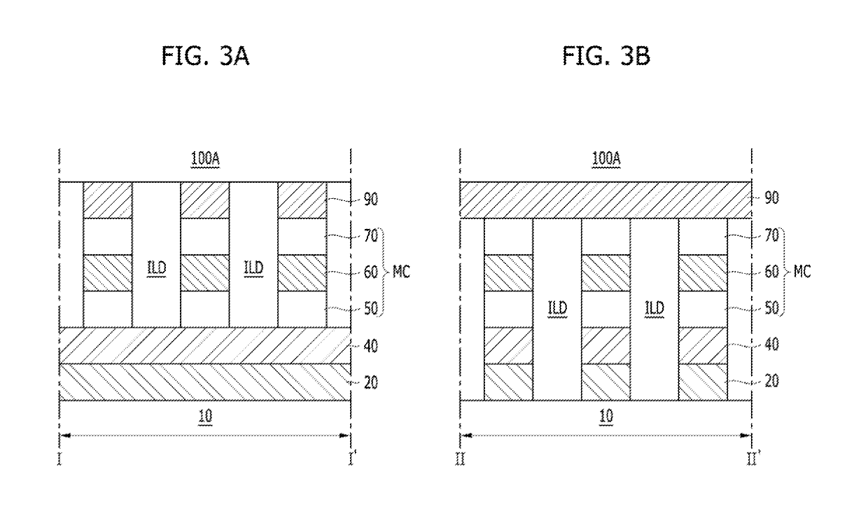

FIGS. 4A and 4B are cross-sectional views of the semiconductor memory device 100B shown in FIG. 2B in accordance with an embodiment of the present disclosure. The cross-sectional views of the semiconductor memory device 100B are taken along lines III-III′ and IV-IV′ of FIG. 2B.

Referring to FIGS. 4A and 4B, the semiconductor memory device 100B in accordance with the embodiment of the present disclosure includes lower conductive interconnections 20 stacked on a lower layer 10, memory cell stacks MC disposed on the lower conductive interconnections 20, selection interconnections 40 disposed on the memory cell stacks MC, and upper conductive interconnects 90 disposed on the selection interconnections 40. In comparison with the semiconductor memory device 100A shown in FIGS. 3A and 3B, the memory cell stacks MC of the semiconductor memory device 100B may be directly stacked on the lower conductive interconnections 20, and the selection interconnections 40 may be disposed between the memory cell stacks MC and the upper conductive interconnections 90.

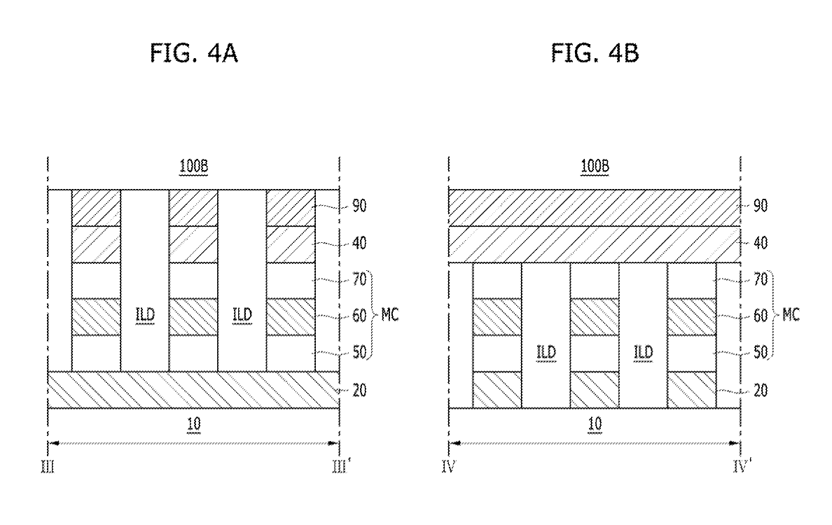

FIGS. 5A and 5B are cross-sectional views of the semiconductor memory device 100C shown in FIG. 2C in accordance with an embodiment of the present disclosure. The cross-sectional views of the semiconductor memory device 100C are taken along lines V-V′ and VI-VI′ of FIG. 2C.

Referring to FIGS. 5A and 5B, the semiconductor memory device 100C in accordance with the embodiment of the present disclosure may include lower conductive interconnections 20 disposed on a lower layer 10, lower barrier interconnections 30 disposed on the lower conductive interconnection 20, selection interconnections 40 disposed on the lower barrier interconnections 30, memory cell stacks MC disposed on the selection interconnections 40, and upper conductive interconnections 90 disposed on the memory cell stacks MC.

Specifically, in comparison with the semiconductor memory device 100A shown in FIG. 3A and FIG. 3B, the lower barrier interconnections 30 of the semiconductor memory device 100C may be disposed between the lower conductive interconnections 20 and the selection interconnections 40. The lower barrier interconnections 30 may include diffusion barrier layers for blocking the diffusion of atoms between the lower conductive interconnections 20 and the selection interconnections 40. For example, the lower barrier interconnections 30 may include a metal, such as any of tungsten (W), titanium (Ti), tantalum (Ta), aluminum (Al), and copper (Cu); a metal compound, such as any of tungsten nitride (WN), titanium nitride (TiN), and tantalum nitride (TaN); a conductor containing carbon (C); another type of conductive material; or a combination thereof.

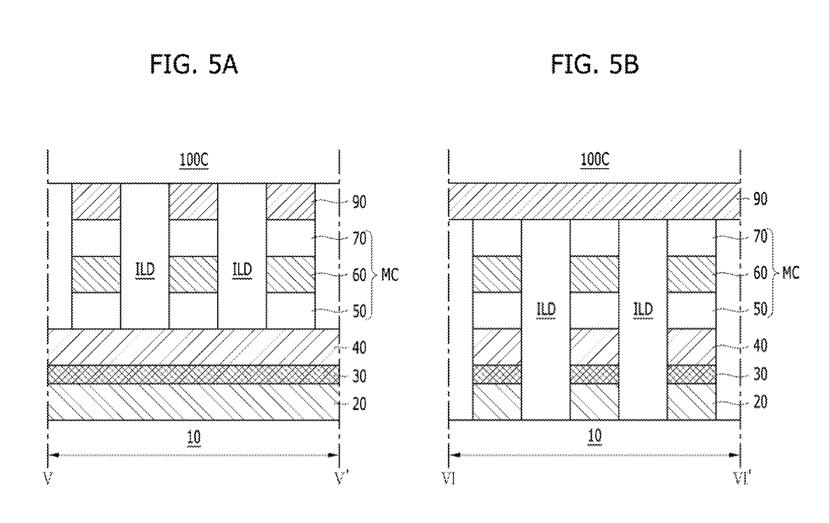

FIGS. 6A and 6B are cross-sectional views of the semiconductor memory device 100D shown in FIG. 2D in accordance with an embodiment of the present disclosure. The cross-sectional views of the semiconductor memory device 100D are taken along lines VII-VII′ and VIII-VIII′ of FIG. 2D.

Referring to FIGS. 6A and 6B, the semiconductor memory device 100D in accordance with the embodiment of the present disclosure may include lower conductive interconnections 20 disposed on a lower layer 10, memory cell stacks MC disposed on the lower conductive interconnections 20, selection interconnections 40 disposed on the memory cell stacks MC, upper barrier interconnections 80 disposed on the selection interconnections 40, and upper conductive interconnections 90 disposed on the upper barrier interconnections 80. Specifically, in comparison with the semiconductor memory device 100B shown in FIGS. 4A and 4B, the upper barrier interconnections 80 of the semiconductor memory device 100D may be disposed between the selection interconnections 40 and the upper conductive interconnections 90. The upper barrier interconnections 80 may include diffusion barrier layers for blocking the diffusion of atoms between the upper conductive interconnections 90 and the selection interconnections 40. For example, the upper barrier interconnections 80 may include a metal, such as any of tungsten (W), titanium (Ti), tantalum (Ta), aluminum (Al), and copper (Cu); a metal compound, such as any of tungsten nitride (WN), titanium nitride (TiN), and tantalum nitride (TaN); a conductor containing carbon (C); another type of conductive material; or a combination thereof.

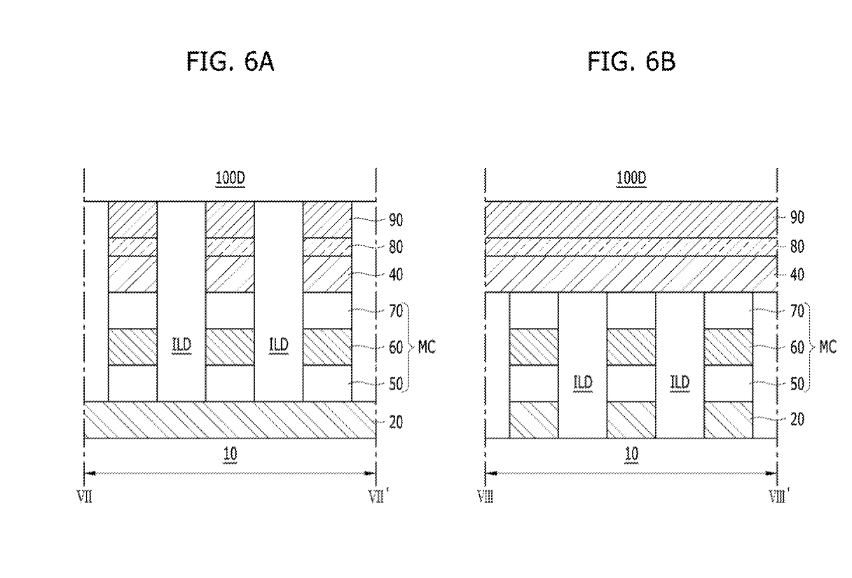

FIGS. 7A and 7B to FIGS. 10A and 10B are cross-sectional views illustrating a method of forming the semiconductor memory device 100A shown in FIG. 2A in accordance with an embodiment of the present disclosure. For example, FIGS. 7A and 7B through FIGS. 10A and 10B are cross-sectional views taken along lines I-I′ and II-II′ of FIG. 2A.

Referring to FIGS. 7A and 7B, the method of forming the semiconductor memory device 100A in accordance with the embodiment of the present disclosure may include sequentially forming a lower conductive interconnection material layer 20a, a selection interconnection material layer 40a, an intermediate electrode material layer 50a, a variable resistive material layer 60a, and an upper electrode material layer 70a on a lower layer 10, and forming a first mask pattern M1 on the upper electrode material layer 70a.

The lower layer 10 may include a semiconductor substrate, and may further include an insulating material layer disposed on the semiconductor substrate.

Forming the lower conductive interconnection material layer 20a may include forming a conductive layer on the lower layer 10 by performing a deposition process. The conductive layer may include a conductive material, such as a metal, a metal alloy, a metal compound, a metal silicide, or a combination thereof.

Forming the selection interconnection material layer 40a may include forming a selection material layer on the lower conductive interconnection material layer 20a by performing a deposition process. The selection material layer may include an Ovonic Threshold Switch (OTS) material layer; a Metal-Insulator Transition (MIT) material layer (MIT) including an MIT material, such as vanadium di-oxide (VO₂), niobium oxide (NbO₂), or a combination thereof; a Mixed Ionic Electronic Conduction (MIEC) material layer; a Metal-Insulator-Metal (MIM) stack layer; a metal oxide layer including a metal oxide material, such as hafnium oxide (HfOₓ); a metal-doped silicon oxide layer; a chalcogenide material layer; a phase changeable material layer including a phase change material, such as GST (GeSbTe); a switching material layer including a switching structure, such as a diode; or a combination thereof.

Forming the intermediate electrode material layer 50a may include forming a conductive layer on the selection interconnection material layer 40a by performing a deposition process. The conductive layer may include a conductive material, such as a metal, a metal alloy, a metal compound, a metal silicide, or a combination thereof. The intermediate electrode material layer 50a may include a barrier metal layer.

Forming the variable resistive material layer 60a may include forming a layer including a variable resistive material on the intermediate electrode material layer 50a by performing a deposition process. The variable resistive material may include one or more of a transition metal oxide, a phase change material (e.g., GST), a magneto resistive material, and another type of variable resistive material.

Forming the upper electrode material layer 70a may include forming a conductive layer on the variable resistive material layer 60a by performing a deposition process. The conductive layer may include a conductive material, such as a metal, a metal alloy, a metal compound, a metal silicide, or a combination thereof. The upper electrode material layer 70a may include a barrier metal layer.

The first mask pattern M1 may have a line shape that extends in a first horizontal direction. Forming the first mask pattern M1 may include forming a photoresist pattern and/or a hard mask pattern by performing a photolithography process and/or a deposition process. The hard mask pattern may include an inorganic material, such as silicon nitride. In another embodiment of the present disclosure, the hard mask pattern may include multiple inorganic material layers that each include an inorganic material pattern, such as a silicon pattern, a silicon oxide pattern, a silicon nitride pattern, a silicon oxynitride pattern, a carbon-containing silicon pattern, or a combination thereof.

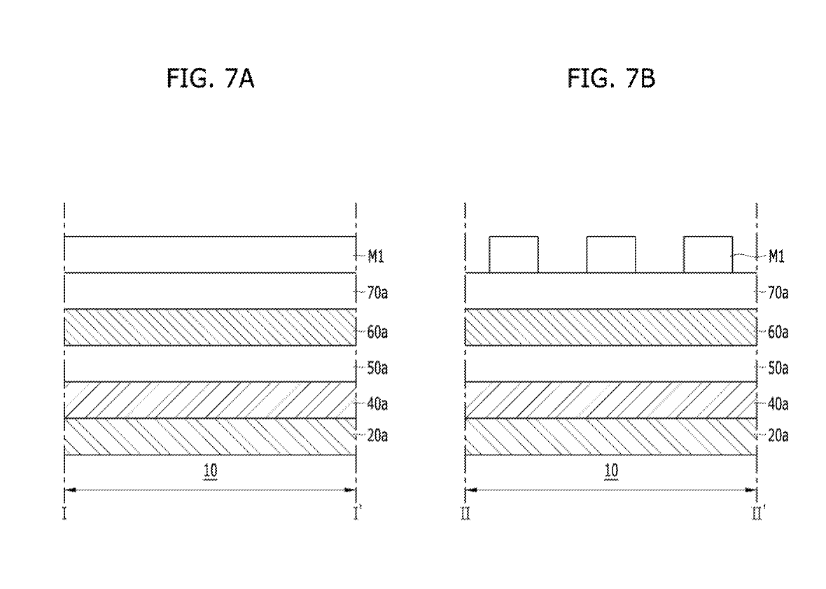

Referring to FIGS. 8A and 8B, the method may include patterning and etching the upper electrode material layer 70a, the variable resistive material layer 60a, the intermediate electrode material layer 50a, the selection interconnection material layer 40a, and the lower conductive interconnection material layer 20a, by performing an etching process using the first mask pattern M1 as an etching mask. Due to the etching process, the lower conductive interconnection material layer 20a and the selection interconnection material layer 40a may be respectively formed into the lower conductive interconnections 20 and the selection interconnections 40, which each have line shapes extending in the first horizontal direction. The intermediate electrode material layer 50a, the variable resistive material layer 60a, and the upper electrode material layer 70a may be respectively formed into intermediate electrode patterns 50b, variable resistive patterns 60b, and upper electrode patterns 70b, which each have line shapes.

In addition, the method may further include removing the first mask pattern M1, and forming an interlayer insulating layer ILD between the lower conductive interconnections 20, the selection interconnections 40, the intermediate electrode patterns 50b, the variable resistive patterns 60b, and the upper electrode patterns 70b. The interlayer insulating layer ILD may include an insulating material, such as silicon oxide, silicon nitride, silicon, a silicon oxide compound including carbon (C) and/or hydrogen (H), or a combination thereof. In another embodiment of the present disclosure, air gaps may present between the memory cell stacks MC. In another embodiment of the present disclosure, after forming the interlayer insulating layer ILD, a CMP (chemical mechanical polishing) process may be performed on the interlayer insulating layer ILD in order to expose an upper surface of the upper electrode patterns 70b.

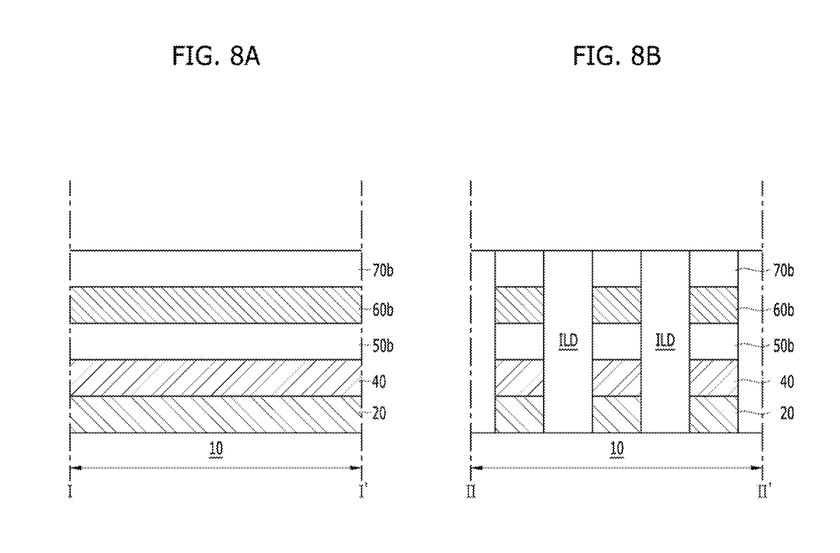

Referring to FIGS. 9A and 9B, the method may include forming an upper conductive interconnection material layer 90a on the upper electrode patterns 70b and the interlayer insulating layer ILD, and forming a second mask pattern M2 on the upper conductive interconnection material layer 90a. Forming the upper conductive interconnection material layer 90a may include forming a conductive layer on the upper electrode patterns 70b and the interlayer insulating layer ILD by performing a deposition process. The conductive layer may include a metal, a metal alloy, a metal compound, a metal silicide, or a combination thereof. The second mask pattern M2 may have a line shape that extends in a second horizontal direction. Forming the second mask pattern M2 may include forming a photoresist pattern and/or a hard mask pattern, by performing a photolithography process and/or a deposition process.

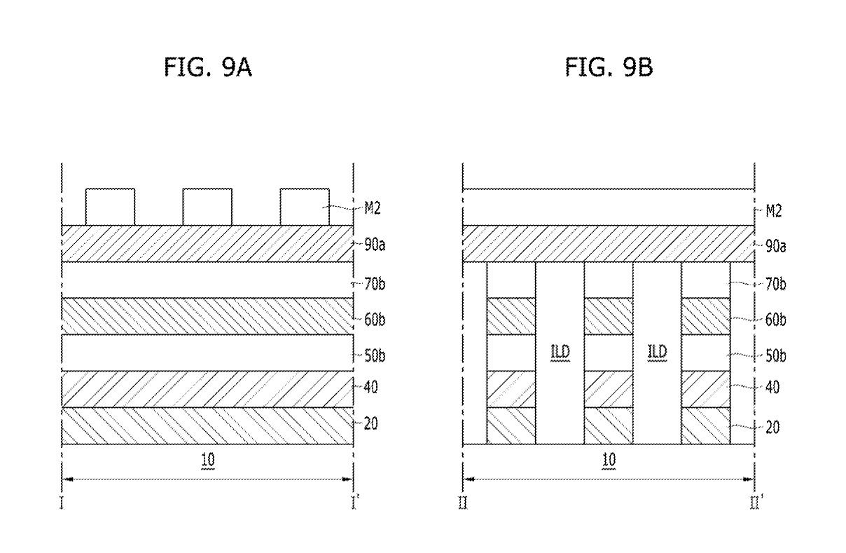

Referring to FIGS. 10A and 10B, the method may include patterning the upper conductive interconnection material layer 90a, the upper electrode patterns 70b, the variable resistive patterns 60b, and the intermediate electrode patterns 50b, by performing an etching process using the second mask pattern M2 as an etch mask. Due to the etching process, the upper electrode patterns 70b, the variable resistive patterns 60b, and the intermediate electrode patterns 50b may be respectively formed into the upper electrodes 70, the variable resistive elements 60, and the intermediate electrodes 50, respectively. Therefore, the pillar shaped memory cell stacks MC including the upper electrodes 70, the variable resistive elements 60, and the intermediate electrodes 50 can be formed. The method may further include removing the second mask pattern M2. Subsequently, referring to FIGS. 3A and 3B, the method may include filling spaces between the upper conductive interconnections 90 and spaces between the pillar shaped memory cell stacks MC in the first horizontal direction with an interlayer insulating layer ILD. Further, the method may include covering upper surfaces of the upper conductive interconnections 90 with one or more additional structures (not illustrated).

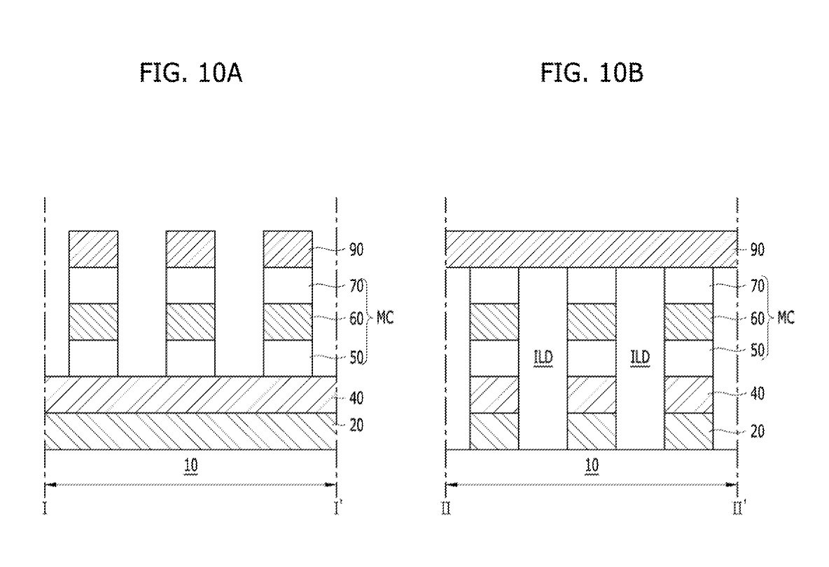

FIGS. 11A and 11B to FIGS. 14A and 14B are cross-sectional views illustrating a method of forming the semiconductor memory device 100B shown in FIG. 2B in accordance with an embodiment of the present disclosure. For example, FIGS. 11A and 11B to FIGS. 14A and 14B are cross-sectional views taken along lines III-III′ and IV-IV′ of FIG. 2B.

Referring to FIGS. 11A and 11B, the method of forming the semiconductor memory device 100B in accordance with an embodiment of the present disclosure includes sequentially forming, on a lower layer 10, a lower conductive interconnection material layer 20a, an intermediate electrode material layer 50a, a variable resistive material layer 60a, and an upper electrode material layer 70a, and forming a first mask pattern M1 on the upper electrode material layer 70a. The first mask pattern M1 may have a line shape that extends in a first horizontal direction.

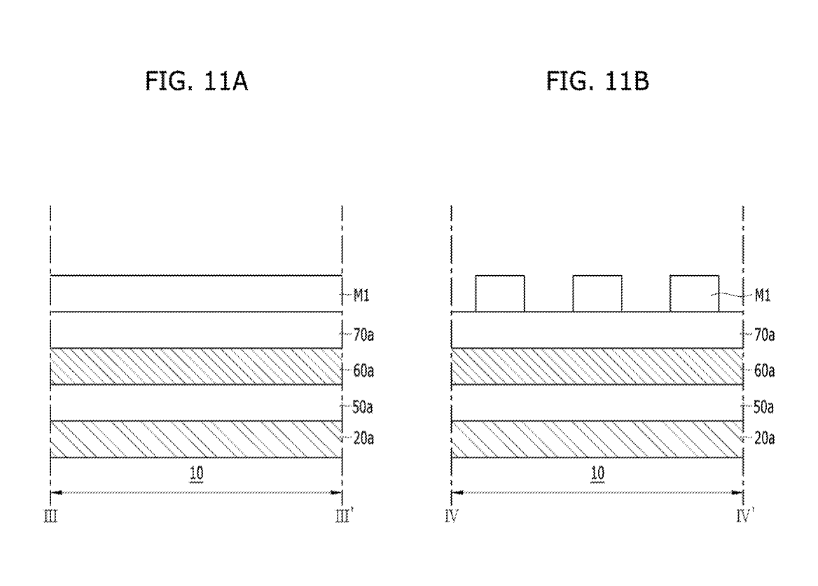

Referring to FIGS. 12A and 12B, the method may include patterning the upper electrode material layer 70a, the variable resistive material layer 60a, the intermediate electrode material layer 50a, and the lower conductive interconnection material layer 20a, by performing an etching process using the first mask pattern M1 as an etch mask. Due to the etching process, the lower conductive interconnection material layer 20a may be formed into lower conductive interconnections 20, which have line shapes extending in the first horizontal direction. The etching process may also form the intermediate electrode material layer 50a, the variable resistive material layer 60a, and the upper electrode material layer 70a into intermediate electrode patterns 50b, variable resistive patterns 60b, and upper electrode patterns 70b, respectively, which have line shapes. The method may further include removing the first mask pattern M1, and forming an interlayer insulating layer ILD between the lower conductive interconnections 20, the intermediate electrode patterns 50b, the variable resistive patterns 60b, and the upper electrode patterns 70b.

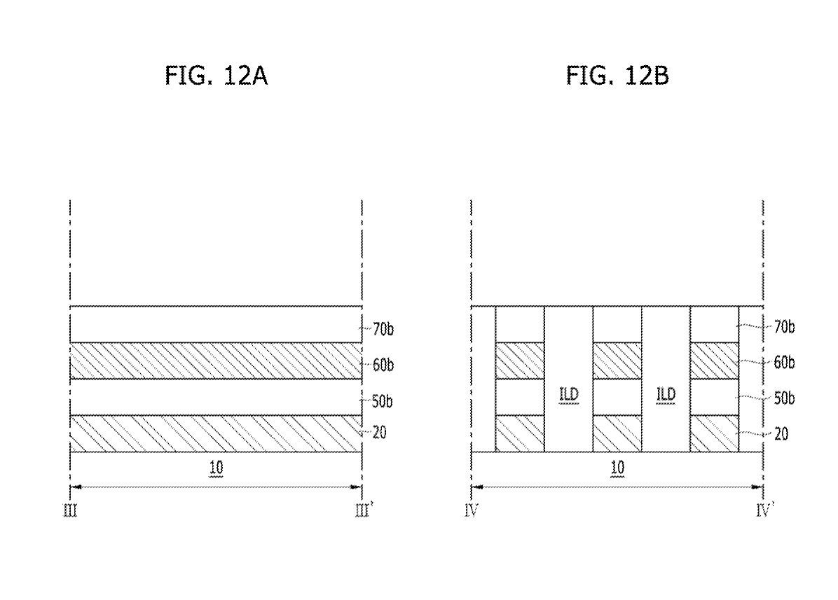

Referring to FIGS. 13A and 13B, the method may include forming a selection interconnection material layer 40a and an upper conductive interconnection material layer 90a on the upper electrode patterns 70b and the interlayer insulating layer ILD, and forming a second mask pattern M2 on the upper conductive interconnection material layer 90a. The second mask pattern M2 may have a line shape that extends in a second horizontal direction.

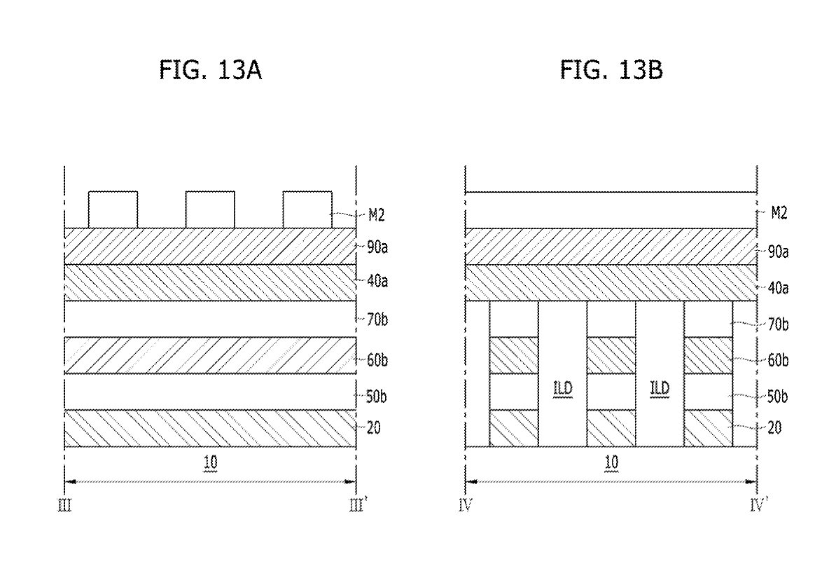

Referring to FIGS. 14A and 14B, the method may include patterning the upper conductive interconnection material layer 90a, the selection interconnection material layer 40a, the upper electrode patterns 70b, the variable resistive patterns 60b, and the intermediate electrode patterns 50b, by performing an etching process using the second mask pattern M2 as an etching mask. Due to the etching process, the upper electrode patterns 70b, the variable resistive patterns 60b, and the intermediate electrode patterns 50b may be formed into pillar shaped memory cell stacks MC, which include the upper electrodes 70, the variable resistive elements 60, and the intermediate electrodes 50. Due to the etching process, the upper conductive interconnection material layer 90a and the selection interconnection material layer 40a may be respectively formed into the upper conductive interconnections 90 and the selection interconnections 40. The method may further include removing the second mask pattern M2. Subsequently, referring to FIGS. 4A and 4B, the method may include forming an interlayer insulating layer ILD between the pillar shaped memory cell stacks MC, the selection interconnections 40, and the upper interconnections 90 in the first horizontal direction. The method may further include covering upper surfaces of the upper conductive interconnections 90 with one or more additional structures (not illustrated).

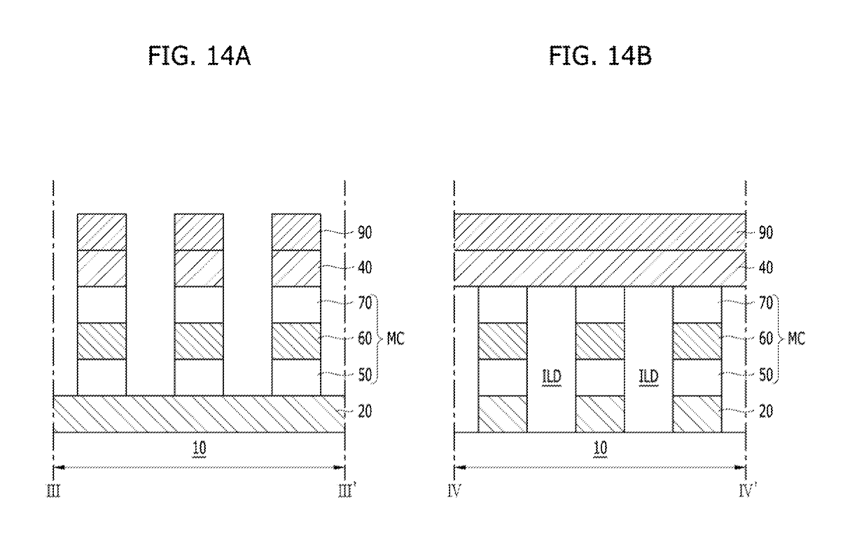

FIGS. 15A and 15B to FIGS. 20A and 20B are cross-sectional views illustrating a method of forming the semiconductor memory device 100C shown in FIG. 2C in accordance with an embodiment of the present disclosure. For example, FIGS. 15A and 15B to FIGS. 20A and 20B are cross-sectional views taken along lines V-V′ and VI-VI′ of FIG. 2C.

Referring to FIGS. 15A and 15B, the method of forming the semiconductor memory device 100C in accordance with an embodiment of the present disclosure may include forming, on a lower layer 10, a lower conductive interconnection material layer 20a, a lower barrier material layer 30a, and a selection interconnection material layer 40a, and forming a first mask pattern M1 on the selection interconnection material layer 40a. The first mask pattern M1 may have a line shape that extends in a first horizontal direction.

The lower barrier material layer 30a may be formed by performing a deposition process. The lower barrier material layer 30a may include a metal layer including one or more metals, such as any of tungsten (W), titanium (Ti), tantalum (Ta), aluminum (Al), and copper (Cu); a metal compound layer including a metal compound, such as any of tungsten nitride (WN), titanium nitride (TiN), and tantalum nitride (TaN); a conductive material layer including one or more materials containing carbon (C); another type of conductive material layer; or a combination thereof.

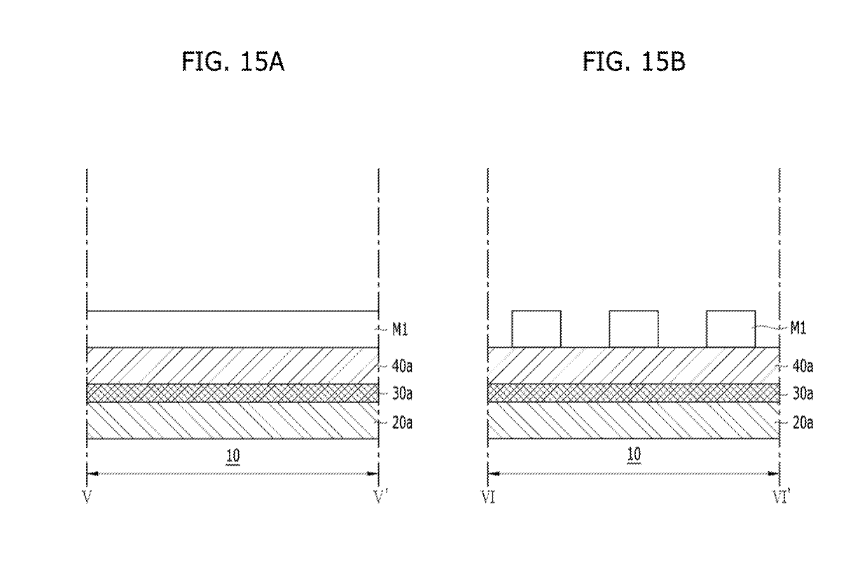

Referring to FIGS. 16A and 16B, the method may include patterning the selection interconnection material layer 40a, the lower barrier material layer 30a, and the conductive interconnection material layer 20a, by performing an etching process using the first mask pattern M1 as an etching mask. Due to the etching process, the lower conductive material layer 20a, the lower barrier material layer 30a, and the selection interconnection material layer 40a may be respectively formed into lower conductive interconnections 20, lower barrier interconnections 30, and selection interconnections 40, which may have line shapes extending in the first horizontal direction. The method may further include removing the first mask pattern M1 and forming an interlayer insulating layer ILD between the lower conductive interconnections 20, the lower barrier interconnections 30, and the selection interconnections 40.

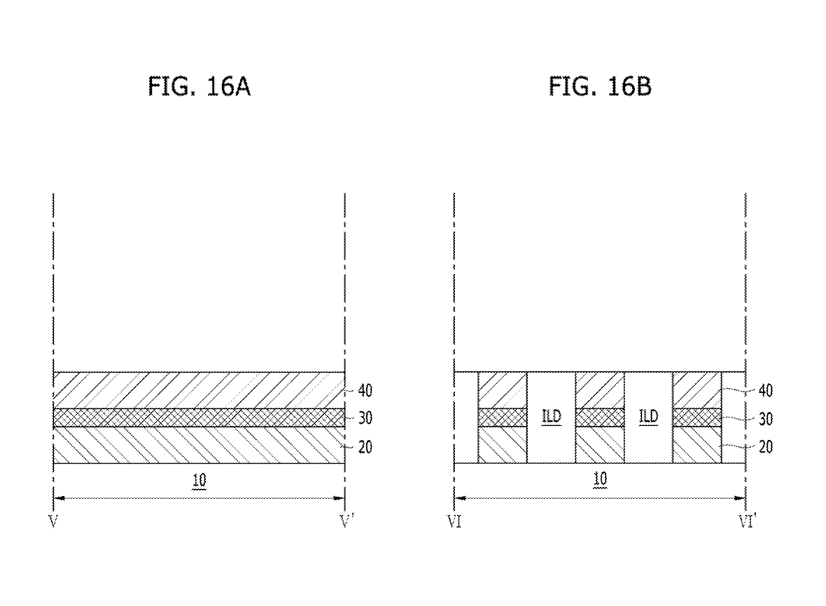

Referring to FIGS. 17A and 17B, the method may include forming an intermediate electrode material layer 50a, a variable resistive material layer 60a, and an upper electrode material layer 70a on the selection interconnections 40 and the interlayer insulating layer ILD, and forming a second mask pattern M2 on the upper electrode material layer 70a. The second mask pattern M2 may have a lattice-shaped island arrangement. For example, the second mask pattern M2 may include an array of island-type sub-patterns that cover portions of the upper electrode material layer 70a. The array of island-type sub-patterns may be arranged in rows and columns extending horizontally across the upper surface of the upper electrode material layer 70a.

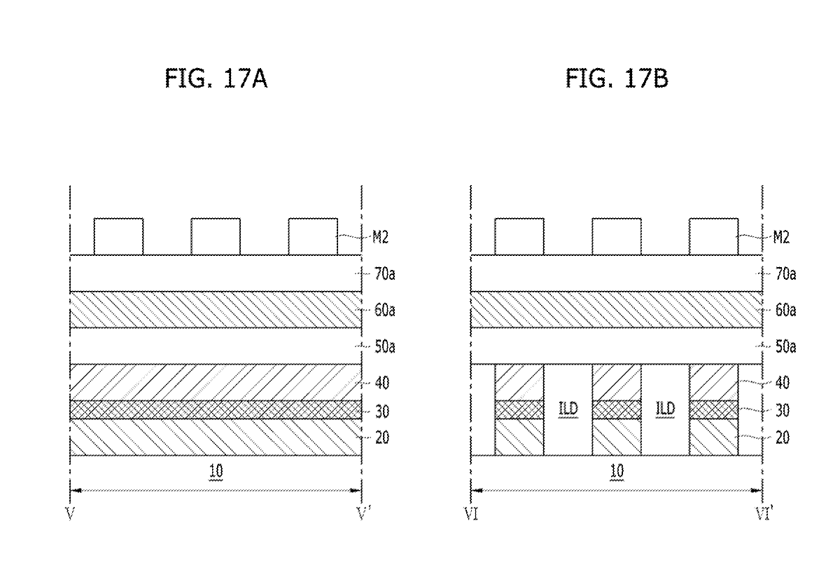

Referring to FIGS. 18A and 18B, the method may include patterning the upper electrode material layer 70a, the variable resistive material layer 60a, and the intermediate electrode material layer 50a, by performing an etching process using the second mask pattern M2 as an etch mask. Due to the etching process, the upper electrode material layer 70a, the variable resistive material layer 60a, and the intermediate electrode material layer 50a may be respectively formed into upper electrodes 70, variable resistive elements 60, and intermediate electrodes 50. Therefore, pillar shaped memory cell stacks MC, which include the upper electrodes 70, the variable resistive elements 60, and the intermediate electrodes 50, can be formed. The pillar shaped memory cell stacks MC may be aligned with the selection interconnections 40 in a vertical direction that is perpendicular to the first and second horizontal directions. The method may further include removing the second mask pattern M2. Subsequently, the method may further include filling spaces between the pillar shaped memory cell stacks MC in the first and second horizontal directions with an interlayer insulating layer ILD.

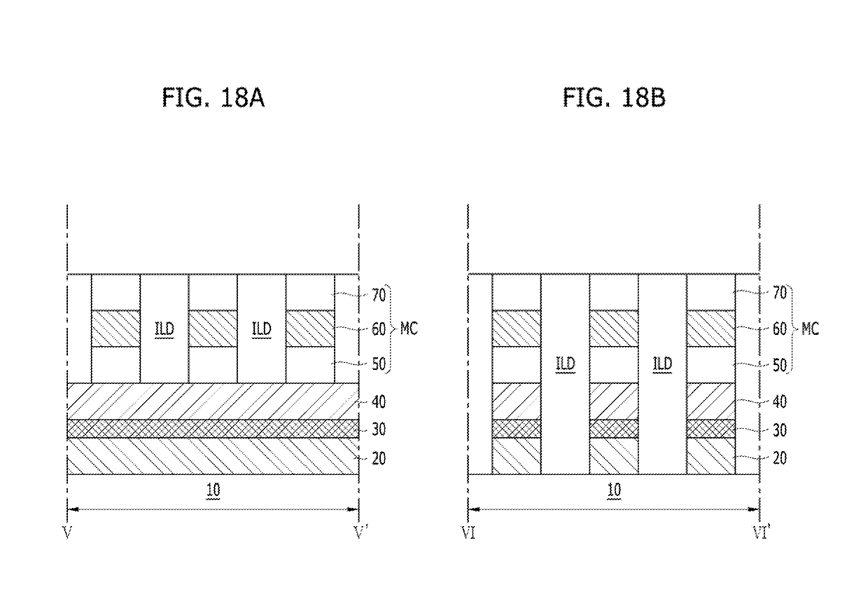

Referring to FIGS. 19A and 19B, the method may include forming an upper conductive interconnection material layer 90a on the upper electrodes 70 of the memory cell stacks MC and on the interlayer insulating layer ILD, and forming a third mask pattern M3 on the upper conductive interconnection material layer 90a. The third mask pattern M3 may have a line shape that extends in the second horizontal direction.

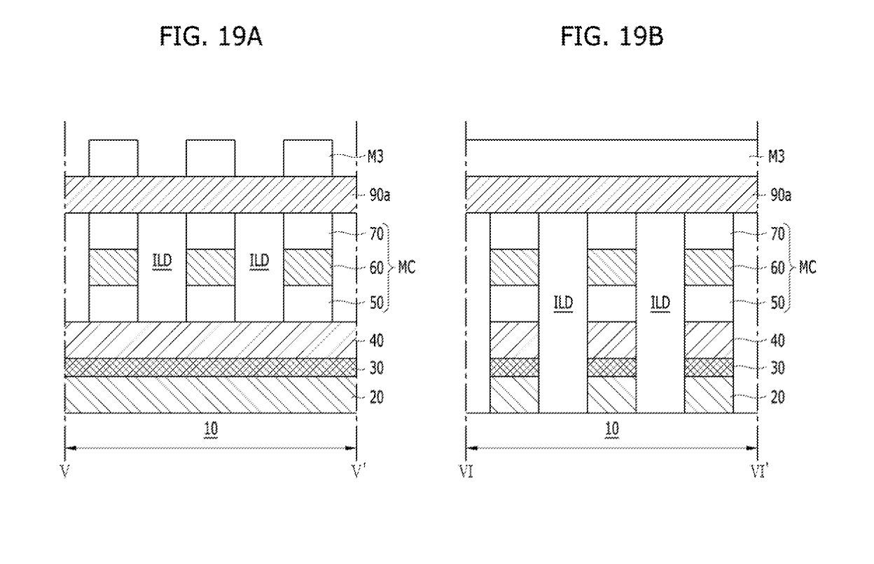

Referring to FIGS. 20A and 20B, the method may include patterning the upper conductive interconnection material layer 90a by performing an etching process using the third mask pattern M3 as an etching mask. Due to the etching process, the upper conductive interconnection material layer 90a may be formed into the upper conductive interconnections 90. The upper conductive interconnections 90 may be aligned with the memory cell stacks MC in the vertical direction. The method may further include removing the third mask pattern M3. Subsequently, referring to FIGS. 5A and 5B, the method may further include filling spaces between the upper conductive interconnections 90 with an interlayer dielectric ILD. The method may further include covering the upper surfaces of the upper conductive interconnections 90 with one or more additional structures (not illustrated).

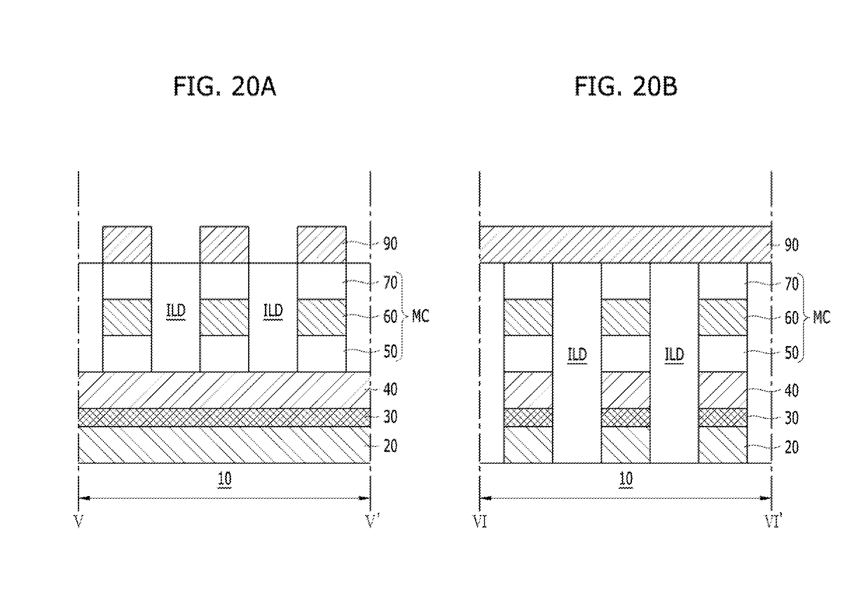

FIGS. 21A and 21B to FIGS. 26A and 26B are cross-sectional views illustrating a method of forming the semiconductor memory device 100D shown in FIG. 2D in accordance with an embodiment of the present disclosure. For example, FIGS. 21A and 21B through FIGS. 26A and 26B are cross-sectional views taken along lines VII-VII′ and VIII-VIII′ of FIG. 2D.

Referring to FIGS. 21A and 21B, the method of forming the semiconductor memory device 100D in accordance with an embodiment of the present disclosure may include sequentially forming a lower conductive interconnection material layer 20a on a lower layer 10, and forming a first mask pattern M1 on the lower conductive interconnection material layer 20a. The first mask pattern M1 may have a line shape that extends in a first horizontal direction.

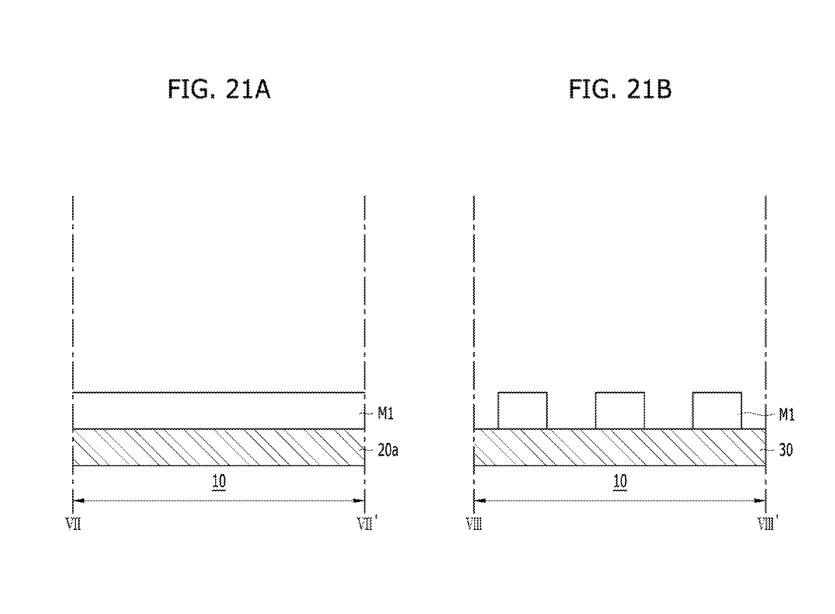

Referring to FIGS. 22A and 22B, the method may include patterning the lower conductive interconnection material layer 20a by performing an etching process using the first mask pattern M1 as an etching mask. Due to the etching process, the lower conductive interconnection material layer 20a may be formed into lower conductive interconnections 20. The method may further include filling spaces between the lower conductive interconnections 20 with an interlayer insulating layer ILD.

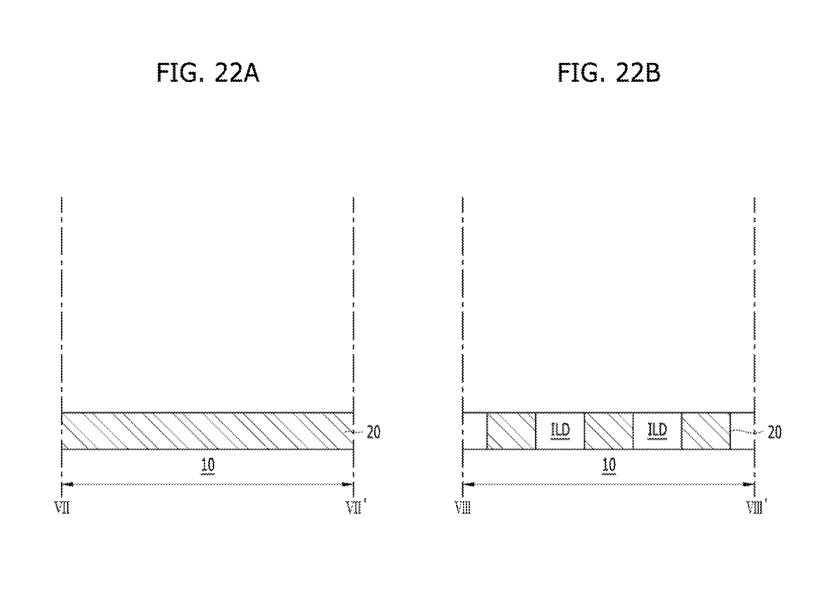

Referring to FIGS. 23A and 23B, the method may include forming, on the lower conductive interconnections 20 and the interlayer insulating layer ILD, an intermediate electrode material layer 50a, a variable resistive material layer 60a, and an upper electrode material layer 70a, and forming a second mask pattern M2 on the upper electrode material layer 70a. The second mask pattern M2 may have a lattice-shaped island arrangement. For example, the second mask pattern M2 may include an array of island-type sub-patterns that cover portions of the upper electrode material layer 70a. The array of island-type sub-patterns may be arranged in rows and columns extending horizontally across the upper surface of the upper electrode material layer 70a.

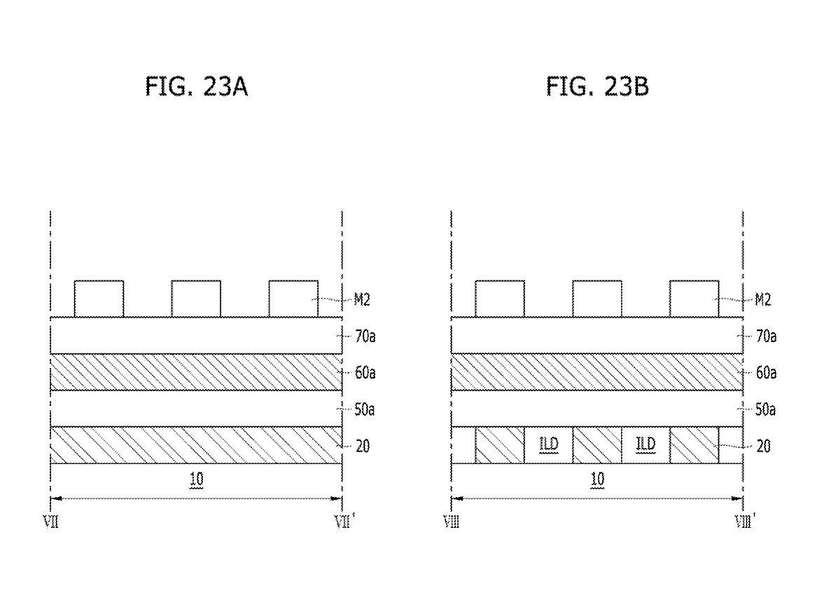

Referring to FIGS. 24A and 24B, the method may include patterning the upper electrode material layer 70a, the variable resistive material layer 60a, and the intermediate electrode material layer 50a, by performing an etching process using the second mask pattern M2 as an etch mask. Due to the etching process, the upper electrode material layer 70a, the variable resistive material layer 60a, and the intermediate electrode material layer 50a may be respectively formed into the upper electrodes 70, the variable resistive elements 60, and the intermediate electrodes 50. Therefore, memory cell stacks MC including the upper electrodes 70, the variable resistive elements 60, and the intermediate electrodes 50 can be formed. The method may further include forming an insulating layer between the memory cell stacks MC. The insulating layer may include the same material as the interlayer insulating layer ILD, and may therefore be part of the interlayer insulating layer ILD. Accordingly, as shown in FIGS. 24A and 24B, the interlayer insulating layer ILD fills spaces between the lower conductive interconnections 20, and spaces between the memory cell stacks MC.

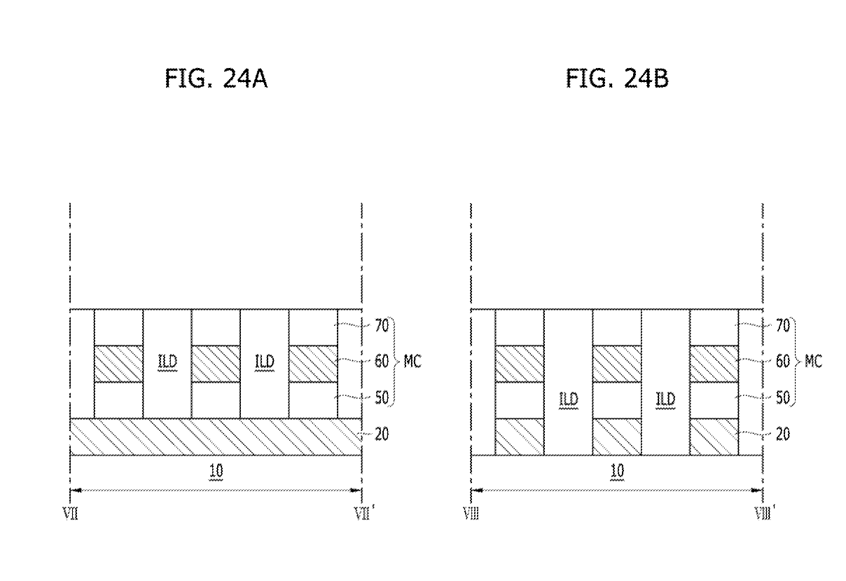

Referring to FIGS. 25A and 25B, the method may include forming, on the upper electrodes 70 of the memory cell stacks MC and the interlayer insulating layer ILD, a selection interconnection material layer 40a, an upper barrier material layer 80a, and an upper conductive interconnection material layer 90a, and forming a third mask pattern M3 on the upper conductive interconnection material layer 90a. The third mask pattern M3 may have a line shape that extends in a second horizontal direction.

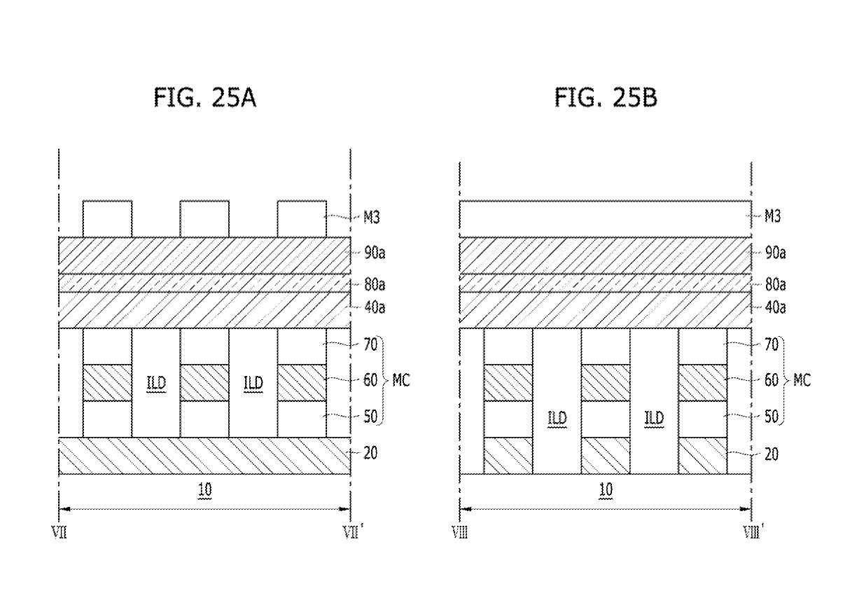

Referring to FIGS. 26A and 26B, the method may include patterning the upper conductive interconnection material layer 90a, the upper barrier material layer 80a, and the selection interconnection material layer 40a, by performing an etching process using the third mask pattern M3 as an etch mask. Due to the etching process, the upper conductive interconnection material layer 90a, the upper barrier material layer 80a, and the selection interconnection material layer 40a may be respectively formed into upper conductive interconnections 90, upper barrier interconnections 80, and selection interconnections 40. The method may further include removing the third mask pattern M3. Subsequently, referring to FIGS. 6A and 6B, the method may further include filling spaces between the upper conductive interconnections 90, spaces between the upper barrier interconnections 80, and spaces between the selection interconnections 40 with an insulating material. The insulating material may include the same material as the interlayer insulating layer ILD, and may therefore be part of the interlayer insulating layer ILD. Accordingly, as shown in FIGS. 26A and 26B, the interlayer insulating layer ILD fills the spaces between the upper conductive interconnections 90, the spaces between the upper barrier interconnections 80, and the spaces between the selection interconnections 40.

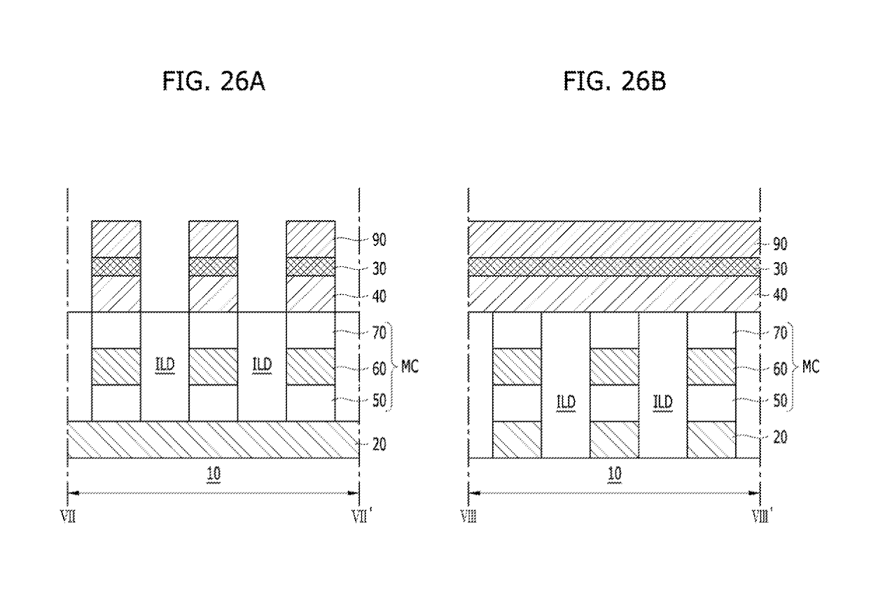

The semiconductor memory devices 100A-100D in accordance with embodiments of the present disclosure may be used in various electronic systems. FIGS. 27 to 31 are electronic systems that include one or more of the semiconductor memory devices 100A-100D in accordance with embodiments of the present disclosure.

FIG. 27 is a block diagram schematically illustrating a microprocessor including one or more of the semiconductor memory devices 100A-100D in accordance with embodiments of the present disclosure. Referring to FIG. 27, a microprocessor 1000 in accordance with an embodiment of the disclosure may perform tasks for controlling and tuning a series of processes for receiving data from various external devices, processing the data, and outputting processing results to external devices. The microprocessor 1000 may include a memory unit 1010, an operation unit 1020, a control unit 1030, and so on. The microprocessor 1000 may be any of various data processing units, such as a central processing unit (CPU), a graphic processing unit (GPU), a digital signal processor (DSP), or an application processor (AP).

The memory unit 1010 is a part which stores data in the microprocessor 1000, as a processor register, register, or the like. The memory unit 1010 may include a data register, an address register, a floating point register, and so on. The memory unit 1010 may include various registers. The memory unit 1010 may perform the function of temporarily storing data for which operations are to be performed by the operation unit 1020, result data of performing the operations, and addresses where data for performing the operations are stored. The storage unit 1010 may include one or more of the semiconductor memory devices 100A-100D in accordance with embodiments of the present disclosure.

The operation unit 1020 may perform four arithmetical operations or logical operations according to results of the control unit 1030 decoding commands. The operation unit 1020 may include one or more arithmetic logic units (ALUs) and so on.

The control unit 1030 may receive signals from the memory unit 1010, from the operation unit 1020, and from a device external to the microprocessor 1000. The control unit 1030 may further perform extraction, decode commands, control input and output of signals of the microprocessor 1000, and execute processing represented by programs.

The microprocessor 1000, in accordance with an embodiment of the present disclosure, may further include a cache memory unit 1040 which can temporarily store data to be inputted from an external device other than the memory unit 1010, or data to be outputted to an external device. In this case, the cache memory unit 1040 may exchange data with the memory unit 1010, the operation unit 1020, and the control unit 1030 through a bus interface 1050.

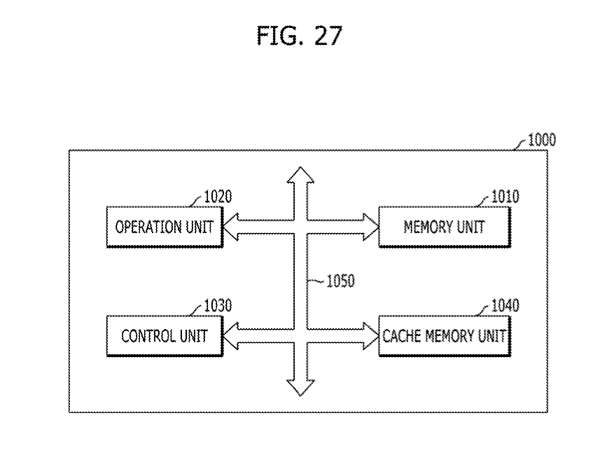

FIG. 28 is a block diagram schematically illustrating a processor that includes one or more of the semiconductor memory devices 100A-100D in accordance with embodiments of the present disclosure. Referring to FIG. 28, a processor 1100 in accordance with an embodiment of the present disclosure may improve performance and realize multi-functionality by including various functions, other than those of a microprocessor, which performs tasks for controlling and tuning a series of processes of receiving data from various external devices, processing the data, and outputting processing results to external devices. The processor 1100 may include a core unit 1110, which serves as the microprocessor; a cache memory unit 1120, which stores data temporarily; and a bus interface 1130 for transferring data between internal and external devices. The processor 1100 may include any of various system-on-chips (SoCs), such as a multi-core processor, a graphic processing unit (GPU), and an application processor (AP).

The core unit 1110 may be a part which performs arithmetic logic operations for data inputted from an external device, and may include a memory unit 1111, an operation unit 1112 and a control unit 1113.

The memory unit 1111 is a part which stores data in the processor 1100, as a processor register, a register, or the like. The memory unit 1111 may include a data register, an address register, a floating point register, and so on. The memory unit 1111 may include various registers. The memory unit 1111 may perform the function of temporarily storing data for which operations are to be performed by the operation unit 1112, result data of performing the operations, and addresses where data for performing of the operations are stored. The operation unit 1112 is a part which performs operations in the processor 1100. The operation unit 1112 may perform four arithmetical operations, logical operations, according to results that the control unit 1113 decodes commands, or the like. The operation unit 1112 may include one or more arithmetic logic units (ALUs) and so on. The control unit 1113 may receive signals from the memory unit 1111, from the operation unit 1112, and from a device external to the processor 1100. The control unit 113 may further perform extraction, decode commands, control input and output of signals of processor 1100, and execute processing represented by programs.

The cache memory unit 1120 is a part which temporarily stores data to compensate for a difference in data processing speed between the core unit 1110 that operates at a high speed and an external device that operates at a low speed. The cache memory unit 1120 may include a primary storage section 1121, a secondary storage section 1122, and a tertiary storage section 1123. In general, the cache memory unit 1120 includes the primary and secondary storage sections 1121 and 1122, and may include the tertiary storage section 1123 in the case where high storage capacity is required. As the occasion demands, the cache memory unit 1120 may include a greater number of storage sections. That is to say, the number of storage sections which are included in the cache memory unit 1120 may be changed according to a design goal. The speeds at which the primary, secondary, and tertiary storage sections 1121, 1122, and 1123 store and disseminate data may be the same or different. In the case where the speeds of the respective storage sections 1121, 1122, and 1123 are different, the speed of the primary storage section 1121 may be the highest. One or more storage sections of the primary storage section 1121, the secondary storage section 1122, and the tertiary storage section 1123 of the cache memory unit 1120 may include one or more of the semiconductor memory devices 100A-100D in accordance with embodiments of the present disclosure.

Although it is shown in FIG. 28 that all the primary, secondary and tertiary storage sections 1121, 1122, and 1123 are configured inside the cache memory unit 1120, it is to be noted that all the primary, secondary, and tertiary storage sections 1121, 1122, and 1123 of the cache memory unit 1120 may be configured outside the core unit 1110 and may compensate for a difference in data processing speed between the core unit 1110 and the external device. Alternatively, it is to be noted that the primary storage section 1121 of the cache memory unit 1120 may be disposed inside the core unit 1110 and the secondary storage section 1122, and that the tertiary storage section 1123 may be configured outside the core unit 1110, to strengthen the function of compensating for a difference in data processing speed. In another embodiment of the present disclosure, the primary and secondary storage sections 1121, 1122 may be disposed inside the core units 1110 and the tertiary storage sections 1123 may be disposed outside the core units 1110.

The bus interface 1130 is a part which connects the core unit 1110, the cache memory unit 1120, and external device, and allows data to be efficiently transmitted.

The processor 1100 in accordance with an embodiment of the present disclosure may include a plurality of core units 1110, and the plurality of core units 1110 may share the cache memory unit 1120. The plurality of core units 1110 and the cache memory unit 1120 may be directly connected or be connected through the bus interface 1130. The plurality of core units 1110 may be configured in the same way as the above-described configuration of the core unit 1110. When the processor 1100 includes the plurality of core unit 1110, the primary storage section 1121 of the cache memory unit 1120 may be configured in each core unit 1110 in correspondence to the number of the plurality of core units 1110, and the secondary storage section 1122, and the tertiary storage section 1123 may be configured outside the plurality of core units 1110 in such a way as to be shared through the bus interface 1130. The processing speed of the primary storage section 1121 may be greater than the processing speeds of the secondary and tertiary storage section 1122 and 1123. In another embodiment of the present disclosure, the primary storage section 1121 and the secondary storage section 1122 may be configured in each core unit 1110 in correspondence to the number of the plurality of core units 1110, and the tertiary storage section 1123 may be configured outside the plurality of core units 1110 in such a way as to be shared through the bus interface 1130.

The processor 1100 in accordance with an embodiment of the present disclosure may further include an embedded memory unit 1140 which stores data, a communication module unit 1150 which can transmit and receive data to and from an external device in a wired or wireless manner, a memory control unit 1160 which drives an external memory device, and a media processing unit 1170 which processes the data processed in the processor 1100 or the data inputted from an external input device and outputs the processed data to an external interface device and so on. The processor 1100 may also include a plurality of various modules and devices. In this case, the plurality of modules which are added may exchange data with the core units 1110 and the cache memory unit 1120 and with one another, through the bus interface 1130.

The embedded memory unit 1140 may include not only a volatile memory but also a nonvolatile memory. The volatile memory may include any of a DRAM (dynamic random access memory), a mobile DRAM, an SRAM (static random access memory), a memory with similar functions to the above mentioned memories, and so on. The nonvolatile memory may include any of a ROM (read only memory), a NOR flash memory, a NAND flash memory, a phase change random access memory (PRAM), a resistive random access memory (RRAM), a spin transfer torque random access memory (STTRAM), a magnetic random access memory (MRAM), and a memory with similar functions. The communication module unit 1150 may include a module capable of being connected with a wired network, a module capable of being connected with a wireless network, or both. The wired network module may include a local area network (LAN), a universal serial bus (USB), an Ethernet, power line communication (PLC) components, such as various devices which send and receive data through transmit lines, and so on. The wireless network module may include Infrared Data Association (IrDA), code division multiple access (CDMA), time division multiple access (TDMA), frequency division multiple access (FDMA), a wireless LAN, Zigbee, a ubiquitous sensor network (USN), Bluetooth, radio frequency identification (RFID), long term evolution (LTE), near field communication (NFC), a wireless broadband Internet (Wibro), high speed downlink packet access (HSDPA), wideband CDMA (WCDMA), ultra wideband (UWB), such as various devices which send and receive data without transmit lines, and so on.

The memory control unit 1160 manages and processes data that are transmitted between the processor 1100 and an external storage device according to different communication standards. The memory control unit 1160 may include various memory controllers, for example, devices which may control IDE (Integrated Device Electronics), SATA (Serial Advanced Technology Attachment), SCSI (Small Computer System Interface), RAID (Redundant Array of Independent Disks), an SSD (solid state disk), eSATA (External SATA), PCMCIA (Personal Computer Memory Card International Association), a USB (universal serial bus), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The media processing unit 1170 may process the data processed in the processor 1100 or the data inputted in the forms of image, voice, and others, from the external input device, and may output the data to the external interface device. The media processing unit 1170 may include a graphic processing unit (GPU), a digital signal processor (DSP), a high definition audio device (HD audio), a high definition multimedia interface (HDMI) controller, and so on.

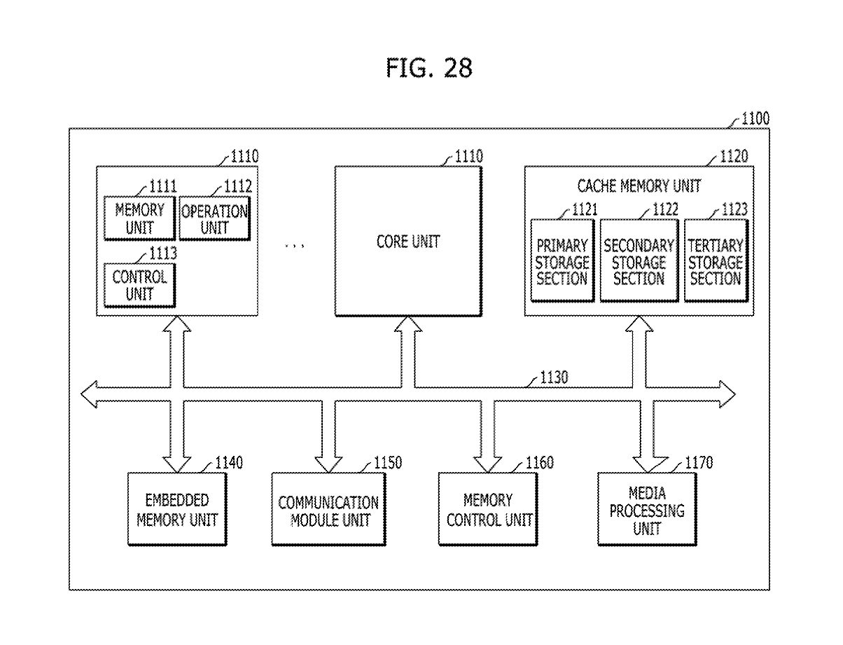

FIG. 29 is a block diagram schematically illustrating an electronic system 1200 including one or more of the semiconductor memory devices 100A-100D in accordance with embodiments of the present disclosure.

Referring to FIG. 29, the electronic system 1200 as an apparatus for processing data may perform input, processing, output, communication, storage, etc. to conduct a series of manipulations for data. The electronic system 1200 may include a processor 1210, a main memory device 1220, an auxiliary memory device 1230, an interface device 1240, and so on. The electronic system 1200 may be various electronic systems which operate using processors, such as a computer, a server, a PDA (personal digital assistant), a portable computer, a web tablet, a wireless phone, a mobile phone, a smart phone, a digital music player, a PMP (portable multimedia player), a camera, a global positioning system (GPS), a video camera, a voice recorder, a telematics, an audio visual (AV) system, a smart television, and so on.

The processor 1210 may decode inputted commands and processes operation, comparison, etc. for the data stored in the system 1200, and controls these operations. The processor 1210 may include a microprocessor unit (MPU), a central processing unit (CPU), a single/multi-core processor, a graphic processing unit (GPU), an application processor (AP), a digital signal processor (DSP), and so on.

The main memory device 1220 is a storage which can temporarily store, call, and execute program codes or data from the auxiliary memory device 1230 when programs are executed, and can conserve memorized contents even when a power supply is cut off. The main memory device 1220 may include one or more of the semiconductor memory devices 100A-100D in accordance with embodiments of the present disclosure. Through this, operating characteristics of the main memory device 1220 may be improved. As a consequence, operating characteristics of the system 1200 may be improved.

The main memory device 1220 may further include a static random access memory (SRAM), a dynamic random access memory (DRAM), and so on, of a volatile memory type in which all contents are erased when a power supply is cut off. Alternatively, the main memory device 1220 may not include the semiconductor memory devices 100A-100D in accordance with embodiments of the present disclosure, but may include a static random access memory (SRAM), a dynamic random access memory (DRAM), and so on, of a volatile memory type in which all contents are erased when a power supply is cut off.

The auxiliary memory device 1230 is a memory device for storing program codes or data. While the speed of the auxiliary memory device 1230 is slower than the main memory device 1220, the auxiliary memory device 1230 can store a larger amount of data. The auxiliary memory device 1230 may also include one or more of the semiconductor memory devices 100A-100D in accordance with embodiments of the present disclosure. Through this, the auxiliary memory device 1230 may be improved. Consequently, operating characteristics of the system 1200 may be improved.

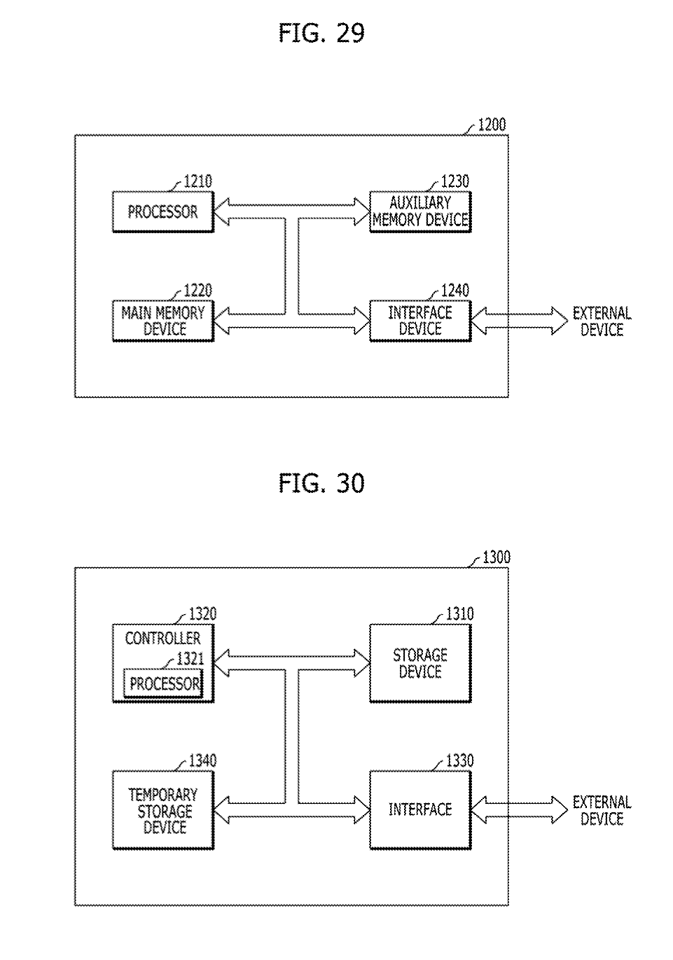

The auxiliary memory device 1230 may further include a data storage system (see the reference numeral 1300 of FIG. 30), such as a magnetic tape using magnetism, a magnetic disk, a laser disk using optics, a magneto-optical disc using both magnetism and optics, a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on. Alternatively, the auxiliary memory device 1230 may not include the semiconductor memory devices 100A-100D in accordance with embodiments of the present disclosure, but may include data storage systems (see the reference numeral 1300 of FIG. 11), such as a magnetic tape using magnetism, a magnetic disk, a laser disk using optics, a magneto-optical disc using both magnetism and optics, a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The interface device 1240 may perform an exchange of commands and data between the system 1200 of the present implementation and an external device. The interface device 1240 may be a keypad, a keyboard, a mouse, a speaker, a mike, a display, various human interface devices (HIDs), a communication device, and so on. The communication device may include a module capable of being connected with a wired network, a module capable of being connected with a wireless network, or both. The wired network module may include a local area network (LAN), a universal serial bus (USB), an Ethernet, power line communication (PLC), such as various devices which send and receive data through transmit lines, and so on. The wireless network module may use and/or include Infrared Data Association (IrDA), code division multiple access (CDMA), time division multiple access (TDMA), frequency division multiple access (FDMA), a wireless LAN, Zigbee, a ubiquitous sensor network (USN), Bluetooth, radio frequency identification (RFID), long term evolution (LTE), near field communication (NFC), a wireless broadband Internet (Wibro), high speed downlink packet access (HSDPA), wideband CDMA (WCDMA), ultra wideband (UWB), etc. The wireless network may include various devices which send and receive data without transmit lines, and so on.

FIG. 30 is a block diagram schematically illustrating a data storage system including one or more of the semiconductor memory devices 100A-100D in accordance with embodiments of the present disclosure. Referring to FIG. 30, a data storage system 1300 may include a storage device 1310 which has a nonvolatile characteristic as a component for storing data, a controller 1320 which controls the storage device 1310, an interface 1330 for connection with an external device, and a temporary storage device 1340 for storing data temporarily. The data storage system 1300 may be a disk type, such as a hard disk drive (HDD), a compact disc read only memory (CDROM), a digital versatile disc (DVD), a solid state disk (SSD), and so on; and a card type, such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The storage device 1310 may include a nonvolatile memory which stores data semi-permanently. The nonvolatile memory may include a ROM (read only memory), a NOR flash memory, a NAND flash memory, a phase change random access memory (PRAM), a resistive random access memory (RRAM), a magnetic random access memory (MRAM), and so on.

The controller 1320 may control exchange of data between the storage device 1310 and the interface 1330. To this end, the controller 1320 may include a processor 1321 for performing an operation for processing commands inputted through the interface 1330 from an external device outside of the data storage system 1300 and so on.

The interface 1330 performs an exchange of commands and data between the data storage system 1300 and the external device. In the case where the data storage system 1300 is a card type, the interface 1330 may be compatible with interfaces which are used in devices, such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on, or be compatible with interfaces which are used in devices similar to the above mentioned devices. In the case where the data storage system 1300 is a disk type, the interface 1330 may be compatible with interfaces, such as IDE (Integrated Device Electronics), SATA (Serial Advanced Technology Attachment), SCSI (Small Computer System Interface), eSATA (External SATA), PCMCIA (Personal Computer Memory Card International Association), a USB (universal serial bus), and so on, or be compatible with the interfaces which are similar to the above mentioned interfaces. The interface 1330 may be compatible with one or more interfaces having a different type from each other.

The temporary storage device 1340 can store data temporarily for efficiently transferring data between the interface 1330 and the storage device 1310 according to diversifications and high performance of an interface with an external device, a controller and a system. The temporary storage device 1340 for temporarily storing data may include one or more of the semiconductor devices 100A-100D in accordance with embodiments of the present disclosure. Through this, operating characteristics of the storage device 1310 or the temporary storage device 1340 may be improved. Consequently, operating characteristics of the data storage system 1300 may be improved.

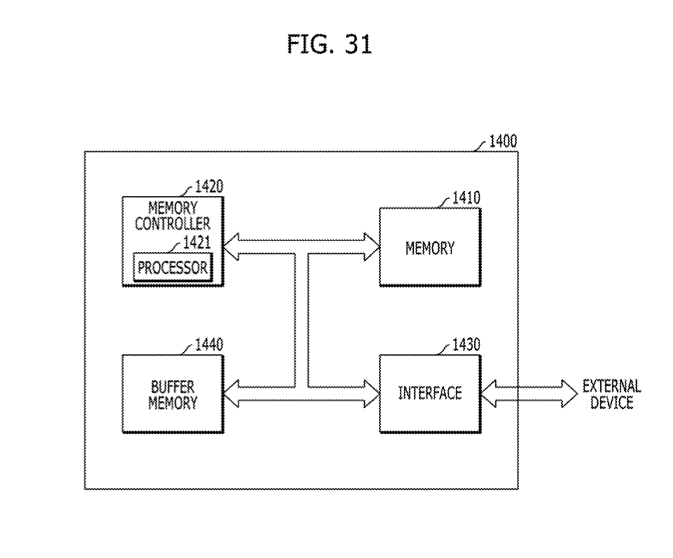

FIG. 31 is a block diagram schematically illustrating a memory system 1400 including one or more of the semiconductor memory devices 100A-100D in accordance with embodiments of the present disclosure. Referring to FIG. 31, a memory system 1400 may include a memory 1410 which has a nonvolatile characteristic as a component for storing data, a memory controller 1420 which controls the memory 1410, an interface 1430 for connection with an external device, and so on. The memory system 1400 may be a card type, such as a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on. The memory 1410 for storing data may include one or more of the semiconductor memory devices 100A-100D in accordance with embodiments of the present disclosure. Through this, operating characteristics of the memory 1410 may be improved. As a consequence, operating characteristics of the memory system 1400 may be improved.

In addition, the memory 1410 according to the present implementation may further include a ROM (read only memory), a NOR flash memory, a NAND flash memory, a phase change random access memory (PRAM), a resistive random access memory (RRAM), a magnetic random access memory (MRAM), and so on, which each have a nonvolatile characteristic.

The memory controller 1420 may control exchange of data between the memory 1410 and the interface 1430. To this end, the memory controller 1420 may include a processor 1421 for performing an operation for and processing commands inputted through the interface 1430 from an external device outside of the memory system 1400. The interface 1430 performs an exchange of commands and data between the memory system 1400 and the external device. The interface 1430 may be compatible with interfaces which are used in devices, such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on, or be compatible with interfaces which are used in devices similar to the above mentioned devices. The interface 1430 may be compatible with one or more interfaces having a different type from each other.

The memory system 1400 according to the present implementation may further include a buffer memory 1440 for efficiently transferring data between the interface 1430 and the memory 1410 according to diversification and high performance of an interface with an external device, a memory controller, and a memory system. For example, the buffer memory 1440 for temporarily storing data may include at least one of the semiconductor memory devices 100A-100D in accordance with embodiments of the present disclosure. Through this, operating characteristics of the buffer memory 1440 may be improved. As a consequence, operating characteristics of the memory system 1400 may be improved.

Moreover, the buffer memory 1440 according to the present implementation may further include any of an SRAM (static random access memory), a DRAM (dynamic random access memory), and so on, which each have a volatile characteristic; and a phase change random access memory (PRAM), a resistive random access memory (RRAM), a spin transfer torque random access memory (STTRAM), a magnetic random access memory (MRAM), and so on, which each have a nonvolatile characteristic. The buffer memory 1440 may not include the semiconductor memory devices 100A-100D in accordance with embodiments of the present disclosure, but may include an SRAM (static random access memory), a DRAM (dynamic random access memory), and so on, which each have a volatile characteristic, and a phase change random access memory (PRAM), a resistive random access memory (RRAM), a spin transfer torque random access memory (STTRAM), a magnetic random access memory (MRAM), and so on, which each have a nonvolatile characteristic.

Features in the above examples of electronic systems in FIGS. 27-31 based on the semiconductor memory devices 100A-100D disclosed in this document may be implemented in various devices, systems, and applications. Some examples include mobile phones or other portable communication devices, tablet computers, notebook or laptop computers, game machines, smart TV sets, TV set top boxes, multimedia servers, digital cameras with or without wireless communication functions, wrist watches or other wearable devices with wireless communication capabilities, and so on.

While this patent document contains many specifics, these should not be construed as limitations on the scope of any disclosure or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately, or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in embodiments described in this patent document should not be understood as requiring such separation in all embodiments.

Only a few embodiments and examples are described. Other implementations, enhancements and variations can be made based on what is described and illustrated in this patent document.

According to embodiments of the present disclosure, the height or thickness of memory cell stacks, which may be subsequently patterned by an etching process or the like, can be reduced. That is, the memory cell stacks may be relatively thin, short, or both. Thus, the etching process for forming the memory cell stacks can be facilitated.

Since the height of the memory cell stack can be reduced, the influence of an inclination of each of the side walls of the memory cell stacks on an area occupied by the memory cell stacks can also be reduced. That is, even if a side wall of a memory cell stack is sloped and nonparallel to a stacking direction, the memory cell stack has a relatively short height, so the slope of the side wall does not necessarily have a significant width, and an area occupied by the memory cell stack is relatively small. Therefore, the degree of integration of a semiconductor memory device according to embodiments of the present disclosure can be improved.

According to embodiments of the present disclosure, a voltage concentrated on a selection interconnection can be reduced, and thus degradation of the device caused by voltage concentration can be mitigated. Therefore, the life of the product can be prolonged.

While specific embodiments of the present disclosure have been described, it will be apparent to those skilled in the art that various changes and modifications may be made without departing from the spirit and scope of the invention as defined in the following claims.

What is claimed is:

1. An electronic system including a semiconductor memory device, wherein the semiconductor memory device comprises:
a plurality of first conductive interconnections extending in parallel in a first horizontal direction;
a plurality of selection interconnections disposed on the first conductive interconnections, the selection interconnections extending in parallel in the first horizontal direction;
a plurality of second conductive interconnections extending in parallel in a second horizontal direction that is perpendicular to the first horizontal direction; and
a plurality of memory cell stacks respectively disposed in interconnection regions between the first conductive interconnections and the second conductive interconnections,
wherein each of the memory cell stacks includes a variable resistive element.

2. The electronic system of claim 1,
wherein each of the selection interconnections comprises one of an Ovonic Threshold Switch (OTS) material layer, a Metal-Insulator Transition (MIT) material layer, a Mixed Ionic Electronic Conduction (MIEC) material layer, a Metal-Insulator-Metal (MIM) stack layer, a metal oxide layer, a metal-doped silicon oxide layer, a chalcogenide material layer, a phase changeable material layer, and a diode.

3. The electronic system of claim 1,
wherein the variable resistive element comprises a variable resistive material including one or more of a transition metal oxide, a phase changeable material, and a magneto-resistive material.

4. The electronic system of claim 1,
wherein each of the memory cell stacks further comprises an upper electrode disposed on the variable resistive element, the upper electrode being in contact with one of the first conductive interconnections.

5. The electronic system of claim 4,
wherein each of the memory cell stacks further comprises an intermediate electrode disposed between one of the selection interconnections and the variable resistive element.

6. The electronic system of claim 5,
wherein the intermediate electrode of each memory cell stack is in contact with one of the selection interconnections.

7. The electronic system of claim 5,
wherein the intermediate electrode and the upper electrode of each memory cell stack include a conductive material comprising one or more of a metal, a metal compound, and a conductor containing carbon (C).

8. The electronic system of claim 1,
wherein the semiconductor memory device further comprises barrier interconnections respectively disposed between the first conductive interconnections and the selection interconnections.

9. The electronic system of claim 8,
wherein the barrier interconnections comprise a conductive material including one or more of a metal, a metal compound, and a conductor containing carbon (C).

10. The electronic system of claim 1, further comprising a microprocessor that includes:
a control unit configured to receive a signal including a command from an external device outside of the microprocessor, and to perform extracting, decoding of the command, or controlling an input or an output of the microprocessor;
an operation unit configured to perform an operation based on a result of the control unit decoding the command; and
a memory unit configured to store data for performing the operation, data corresponding to a result of performing the operation, or an address of data for which the operation is performed,
wherein the semiconductor memory device is part of the memory unit in the microprocessor.

11. The electronic system of claim 1, further comprising a processing system that includes:
a processor configured to decode a command received by the processor and to control an operation for information based on a result of decoding the command;
an auxiliary memory device configured to store a program for decoding the command and the information;
a main memory device configured to call and store the program and the information from the auxiliary memory device, the processor performing the operation using the program and executing the program using the information; and
an interface device configured to perform communication between an external device and at least one of the processor, the auxiliary memory device, and the main memory device,
wherein the semiconductor memory device is part of the auxiliary memory device or the main memory device in the processing system.

12. The electronic system of claim 1, further comprising a data storage system that includes:
a storage device configured to store data and to conserve stored data regardless of power supply;
a controller configured to control input and output of data to and from the storage device according to a command inputted from an external device;
a temporary storage device configured to temporarily store data exchanged between the storage device and the external device; and
an interface configured to perform communication between the external device and at least one of the storage device, the controller, and the temporary storage device,
wherein the semiconductor memory device is part of the storage device or the temporary storage device in the data storage system.

13. An electronic system including a semiconductor memory device, the semiconductor memory device comprising:
first conductive interconnections extending in parallel in a first horizontal direction;
selection interconnections extending in parallel in a second horizontal direction that is perpendicular to the first horizontal direction;
second conductive interconnections disposed on the selection interconnections, the second conductive interconnections extending in parallel in the second horizontal direction; and
memory cell stacks respectively disposed in intersection regions between the first conductive interconnections and the selection interconnections,
wherein each of the memory cell stacks comprises a variable resistive element.

14. The electronic system of claim 13,
wherein the semiconductor memory device further comprises barrier interconnections respectively disposed between the selection interconnections and the second conductive interconnections.

15. The electronic system of claim 13,
wherein each of the memory cell stacks further comprises an upper electrode disposed on the variable resistive element, and
wherein the upper electrode of each of the memory cell stacks is in contact with one of the selection interconnections.

16. The electronic system of claim 13,
wherein each of the memory cell stacks further comprises an intermediate electrode that is disposed between the variable resistive element and one of the first conductive interconnections.

17. A semiconductor memory system, comprising:
first conductive interconnections extending in parallel in a first horizontal direction;
second conductive interconnections extending in parallel in a second horizontal direction that is perpendicular to the first horizontal direction;
memory cell stacks respectively disposed in intersection regions between the first conductive interconnection and the second conductive interconnections; and
selection interconnections disposed between the first conductive interconnections and the memory cell stacks,
wherein the selection interconnections are in contact with the first conductive interconnections and extend in parallel in the first horizontal direction.

18. The semiconductor memory system of claim 17,
wherein each of the memory cell stacks comprises a variable resistive element and a first electrode, and
wherein the first electrode of each of the memory cell stacks is in contact with one of the selection interconnections.

19. The semiconductor memory system of claim 18,
wherein each of the memory cell stacks further comprises a second electrode, and
wherein the second electrode is in contact with one of the second conductive interconnections.

20. The semiconductor memory system of claim 17, further comprising:
barrier interconnections respectively disposed between the selection interconnections and the first conductive interconnections.
